(19) United States
(12) Patent Application Publication
(10) Pub. No.: US 2026/0003181 A1
(43) Pub. Date: Jan. 1, 2026

(54) NON-CONTACT MICROELECTROMECHANICAL SYSTEM DEVICE WITH HINGE-LEVEL ACTUATION

(71) Applicant: TEXAS INSTRUMENTS INCORPORATED, Dallas, TX (US)

(72) Inventors: Nathaniel GILLY, Dallas, TX (US); William C. MCDONALD, Allen, TX (US); John HAMLIN, Dallas, TX (US)

(21) Appl. No.: 19/095,679

(22) Filed: Mar. 31, 2025

Related U.S. Application Data
(60) Provisional application No. 63/666,270, filed on Jul. 1, 2024.

(51) Int. Cl. G02B 26/08; B81B 3/00

(52) U.S. Cl. CPC G02B 26/0833; B81B 3/0008; B81B 2201/042; B81B 2203/0181; B81B 2203/04

(57) ABSTRACT

A microelectromechanical system device includes: a substrate; a first electrode on the substrate; a second electrode on the substrate, a first gap between the first electrode and the second electrode; a third electrode on the substrate; a fourth electrode on the substrate, a second gap between the third electrode and the fourth electrode; a first electrode pad on the substrate; a second electrode pad on the substrate; and a hinge extending between the first electrode pad and the second electrode pad. The hinge has a first extension and a second extension, the first extension over the first gap and the second extension over the second gap.

### CROSS-REFERENCE TO RELATED APPLICATIONS

This application claims priority to U.S. Provisional Application No. 63/666,270, filed Jul. 1, 2024, entitled “NON-CONTACT MICROMIRROR DESIGN USING HINGE LEVEL ACTUATION,” which is hereby incorporated herein by reference in its entirety.

### BACKGROUND

Some microelectromechanical system (MEMS) devices are used in a spatial light modulator (SLM), such as a digital micromirror device (DMD) to form an array of pixels. An example MEMS device selectively switches a mirror between an on position and an off position responsive to control data. Stiction forces between contact points of a MEMS device may negatively affect MEMS device operations and the impact of stiction forces increase as MEMS device dimensions are reduced.

### SUMMARY

In an example, a microelectromechanical system (MEMS) device includes: a substrate; a first electrode on the substrate; a second electrode on the substrate, a first gap between the first electrode and the second electrode; a third electrode on the substrate; a fourth electrode on the substrate, a second gap between the third electrode and the fourth electrode; a first electrode pad on the substrate; a second electrode pad on the substrate; and a hinge extending between the first electrode pad and the second electrode pad. The hinge has a first extension and a second extension, the first extension over the first gap and the second extension over the second gap.

In another example, a MEMS device includes: a first electrode; a second electrode, a first gap between the first electrode and the second electrode; a third electrode; a fourth electrode, a second gap between the third electrode and the fourth electrode; a hinge between the first and the second electrodes and the second and third electrodes. The hinge has a first extension and a second extension. The first extension is over the first gap and the second extension is over the second gap. The MEMS device is configured to: rotate the hinge to a first position in which the first extension is within the first gap and the second extension is spaced away from the second gap; and rotate the hinge to a second position in which the first extension is spaced away from the first gap and the second extension is within the second gap.

In yet another example, a MEMS device includes: a substrate; a first electrode on the substrate; a second electrode on the substrate, a first gap between the first electrode and the second electrode; a third electrode on the substrate; a fourth electrode on the substrate, a second gap between the third electrode and the fourth electrode; a first electrode pad on the substrate; a second electrode pad on the substrate; a hinge extending between the first electrode pad and the second electrode pad; a mirror; and a mirror via between the hinge and the mirror The hinge has a first extension and a second extension, the first extension over the first gap and the second extension over the second gap.

### BRIEF DESCRIPTION OF THE DRAWINGS

FIG. 1 is a block diagram of a system in accordance with various examples.

FIG. 2 illustrates the operation of a mirror in accordance with various examples;

FIG. 3A illustrates in a plan view a portion of a DMD with mirrors in an on state and in an off state;

FIG. 3B illustrates in a cross-sectional view the tilt operations of mirrors in an on state and in an off state in accordance with various examples.

FIG. 4A is an exploded view of a non-contact MEMS device in accordance with various examples.

FIG. 4B is a perspective view of the non-contact MEMS device of FIG. 4A.

FIG. 4C is a cross-sectional view of the non-contact MEMS device of FIG. 4B.

FIG. 4D is a side view of the non-contact MEMS device of FIG. 4A to 4C.

FIG. 5A is a see-through top view of the non-contact MEMS device of FIGS. 4A to 4D.

FIG. 5B is a see-through top view of another non-contact MEMS device.

FIG. 5C is a see-through top view of another non-contact MEMS device.

FIG. 6 is a top view of an electrode layer for a non-contact MEMS device in accordance with various examples.

FIGS. 7A and 7B are perspective views of some of the non-contact MEMS device of FIGS. 4A to 4D and a controller in accordance with various examples.

FIG. 7C is a side view of some of the non-contact MEMS device of FIGS. 4A to 4D with a first mirror position.

FIG. 7D is a side view of some of the non-contact MEMS device of FIGS. 4A to 4D with a second mirror position.

FIGS. 8A and 8B are perspective views of some of the non-contact MEMS device of FIGS. 4A to 4D and a controller in accordance with various examples.

FIG. 8C is a side view of some of the non-contact MEMS device of FIGS. 4A to 4D with a third mirror position.

FIG. 8D is a side view of some of the non-contact MEMS device of FIGS. 4A to 4D with a fourth mirror position.

FIG. 8E is a block diagram of a controller in accordance with various examples.

FIG. 9 is a non-contact MEMS device control method in accordance with various examples.

FIG. 10A is a diagram showing non-contact MEMS device waveforms in accordance with various examples.

FIG. 10B is a control method for a non-contact MEMS device related to the diagram in FIG. 10A.

FIG. 11A is a diagram showing non-contact MEMS device waveforms in accordance with various examples.

FIG. 11B is a control method for a non-contact MEMS device related to the diagram in FIG. 11A.

FIG. 12A is a diagram showing non-contact MEMS device waveforms in accordance with various examples.

FIG. 12B is a control method for a non-contact MEMS device related to the diagram in FIG. 12A.

FIG. 13 is a diagram showing different hinge extension positions in accordance with various examples.

FIGS. 14A to 14C are fabrication methods for a non-contact MEMS device in accordance with various examples.

FIGS. 15A to 15S are cross-sectional views of a non-contact MEMS device related to fabrication methods of FIGS. 14A to 14C.

FIG. 15T is a cross-sectional-view through electrodes of a non-contact MEMS device and related to the fabrication methods of FIGS. 14A to 14C.

### DETAILED DESCRIPTION

The same reference numbers or other reference designators are used in the drawings to designate the same or similar features. Such features may be the same or similar either by function and/or structure.

Described herein is a microelectromechanical system (MEMS) device with layers. Example layers include an electrode layer, a mechanical layer, and a mirror, where vias are coupled between components of such layers. The electrode layer includes electrodes separated by gaps. The mechanical layer includes a hinge with extensions over at least some of the gaps. In some examples, target positions for the mirror are actuated using electrostatic forces between the hinge and electrodes. In some examples, a first target position is based on application of first control voltages to the electrodes and resulting first rotation of the hinge. With the first target position, the extensions of the hinge rotate into or out of gaps between the electrodes and stay in the first target position due to first non-contact (e.g., electrostatic) forces. In some examples, a second target position for the mirror is based on application of second control voltages to the electrodes and resulting second rotation of the hinge. With the second target position, the extensions of the hinge rotate into or out of gaps between the electrodes and stay in the second target position due to second non-contact (e.g., electrostatic) forces. Additional target positions are possible. The MEMS devices described herein are sometimes referred to as “non-contact MEMS devices”. As used herein, a non-contact MEMS device refers to a MEMS device in which hinge actuation and movement of a mirror to target positions do not result in the mirror contacting or being pressed against another object (e.g., a spring tip). Such non-contact MEMS devices reduce or eliminate stiction forces, which may otherwise cause inconsistent actuations and negatively affect MEMS device durability. Non-contact MEMS devices are sometimes contrasted herein with “contact MEMS devices”. As used herein, a “contact MEMS device” is a MEMS device in which hinge actuation and movement of a mirror to target positions results in the mirror contacting or being pressed against another object (e.g., a spring tip).

In some examples, each non-contact MEMS device is a pixel. In different examples, such non-contact MEMS devices are organized into a pixel array for a spatial light modulator (SLM), such as a digital micromirror device (DMD). During operations, the SLM receives data from a controller to control on/off states of pixels of the pixel array. By using a pixel array with non-contact MEMS devices, stiction forces are avoided with resulting benefits such as improved actuation consistency and increased MEMS device durability. With MEMS device miniaturization, the effect of stiction forces increases and thus the importance of avoiding such stiction forces using non-contact MEMS devices increases.

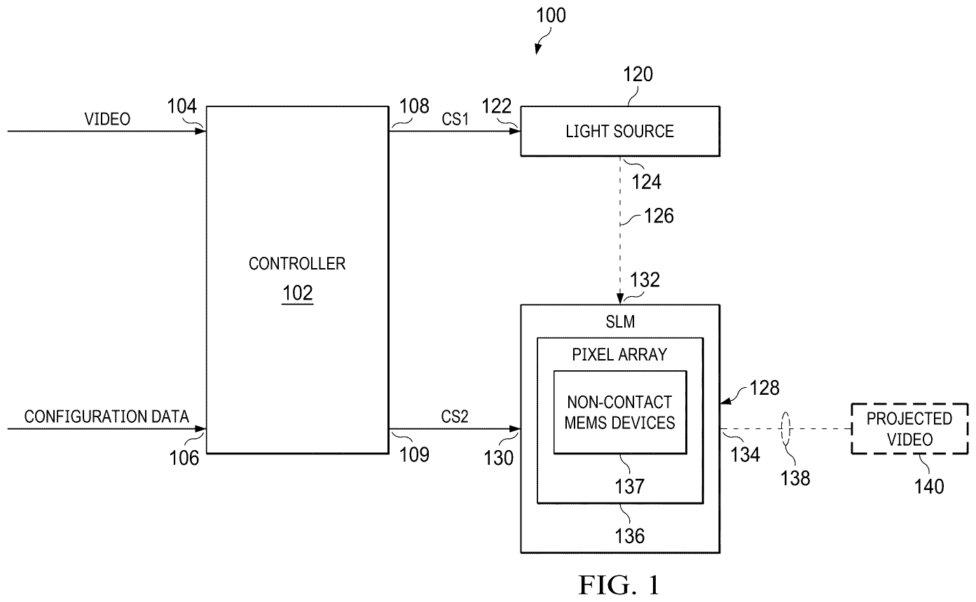

FIG. 1 is a block diagram of a system 100 in accordance with various examples. In some examples, system 100 is a projector, for example a traditional projector, an augmented reality (AR) display, a virtual reality (VR) display, a smart headlight, a heads-up display (HUD), an automotive ground projector, a light detection and ranging (LIDAR) unit, a lithography unit, a three-dimensional (3D) printer, a spectroscopy display, a 3D display, or another type of projector. The system 100 may also represent some or all of a display such as a DMD display.

As shown, system 100 includes a controller 102, a light source 120, an SLM 128, and a projection aperture 138. The controller 102 has a first terminal 104, a second terminal 106, a third terminal 108, and a fourth terminal 109. In different examples, the controller 102 may be an application-specific integrated circuit (ASIC), a field-programmable gate array (FPGA), or a digital controller. The light source 120 has an input 122 and an optical output 124. In different examples, the light source 120 may be a light-emitting diode (LED), a laser, or a laser phosphor illumination system. The SLM 128 has an input 130, an optical input 132, and an optical output 134. In the example of FIG. 1, the SLM 128 includes a pixel array 136 having pixels or non-contact MEMS devices 137. With the non-contact MEMS devices 137, the target positions for each pixel or related mirrors are achieved using non-contact (e.g., electrostatic) forces and avoid contact (e.g., stiction) forces. In different examples, the SLM 128 may perform spatial modulation of light using mechanical, electro-optical, thermo-optical, and/or magneto-optical control options.

In the example of FIG. 1, the controller 102 operates to: receive video data at the first terminal 104; receive configuration data at the second terminal 106; provide control signals CS1 at the third terminal 108 responsive to the video data and the configuration data; and provide control signal CS2 at the fourth terminal 109 responsive to the video and the configuration data. The light source 120 operates to: receive the control signals CS1 at the input 122; and generate light 126 at the optical output 124 responsive to the control signal CS1. In some examples, the light source 120 modulates the intensity, color, and/or timing of the light 126 at the optical output 124 responsive to the control signal CS1. The SLM 128 operates to: receive the control signals CS2 at the input 130; receive the light 126 at the optical input 132; and provide spatially-modulated light at the optical output 134 responsive to the light 126 and the control signals CS2. In some examples, the control signals CS2 include bit plane (BP) data and control signals to control light modulation options of the SLM 128. Without limitation, the control signals CS2 may be transferred to the SLM 128 using low-voltage differential signaling (LVDS). The spatially-modulated light from the SLM 128 results in projected video 140. With the pixel array 136 and related non-contact MEMS devices 137, actuation consistency and durability are improved compared to contact MEMS devices.

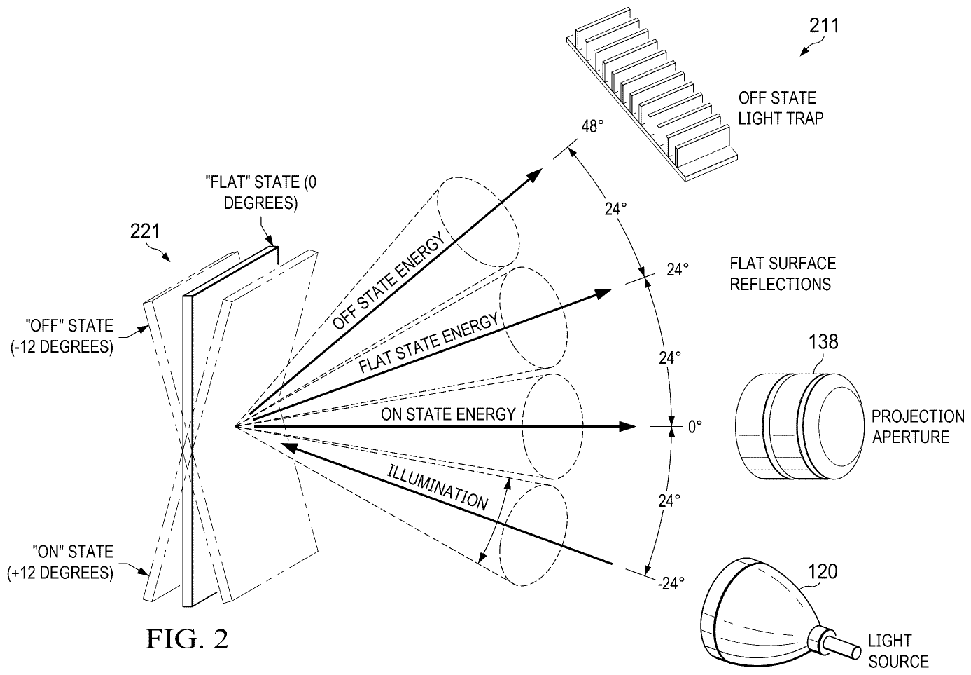

FIG. 2 illustrates the operation of an example mirror 221. A DMD used in the arrangements will have thousands, hundreds of thousands, or even millions of mirrors in a two dimensional array. The example mirror 221 tilts at +/−12 degrees. In DMD devices, varying mirror tilt angles are used such as +/−10 degrees, +/−14 degrees, or +/−17 degrees. When the mirror 221 is not powered, the mirror has a flat state position (sometimes referred to as “rest” position herein), which is designated “FLAT” STATE (0 DEGREES)” in FIG. 2. When the mirror 221 is in an “OFF” STATE, it tilts away from the flat position to a −12 degree position, and the illumination light received from the light source 120 is reflected to be directed away from the projection aperture 138 and towards a light trap 211 designated OFF STATE LIGHT TRAP. When the mirror 221 is in an “ON” STATE, the mirror 221 tilts to a +12 degree position and the illumination light from light source 120 is reflected from the mirror to the projection aperture 138. In different examples, the “ON” STATE and the “OFF” STATE for the mirror 221 and the position of the light trap 211 may vary (e.g., the opposite of the positions represented in FIG. 2).

In the FLAT or rest position state, the reflected light would be directed to the ray labeled FLAT SURFACE REFLECTIONS, however in a system no illumination is presented to mirrors in the FLAT state so little light would be reflected as FLAT SURFACE REFLECTIONS. As is further described below, in a DMD of the arrangements, an array of memory cells in rows and columns is coupled to the array of mirrors, and the memory cells are written with display data. When the mirrors are updated, the entire array of mirrors changes position in correspondence with the pattern stored in the memory array, the mirrors taking positions determined by the data stored in the associated memory cell. In an arrangement for a device, the memory cells are formed in a silicon substrate in rows and columns, and the mirrors form a mirror array, having rows and columns, over the array of memory cells. The mirrors are positioned over corresponding memory cells that store data that control the motion of the individual mirrors.

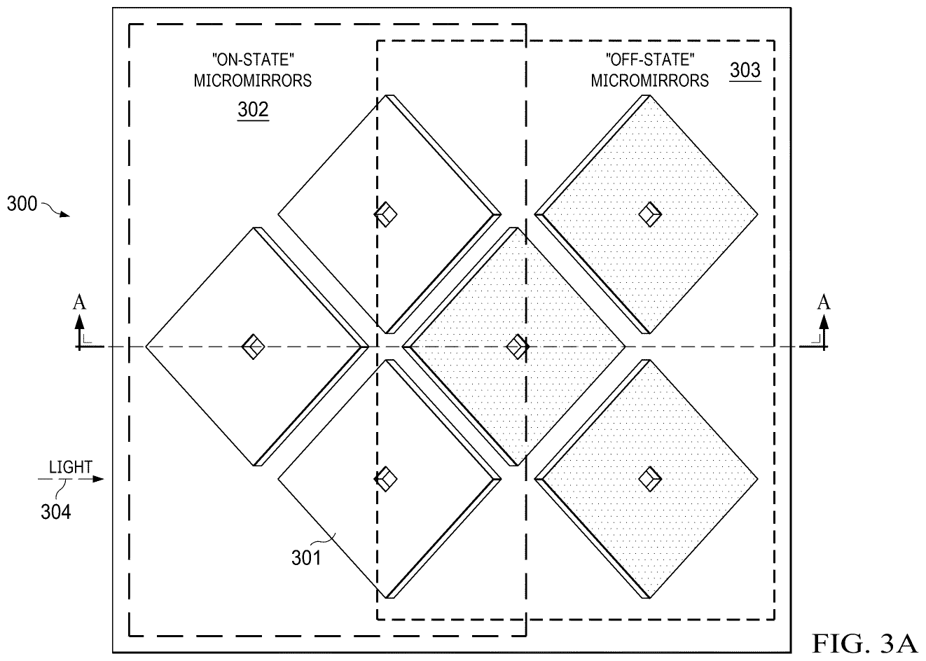

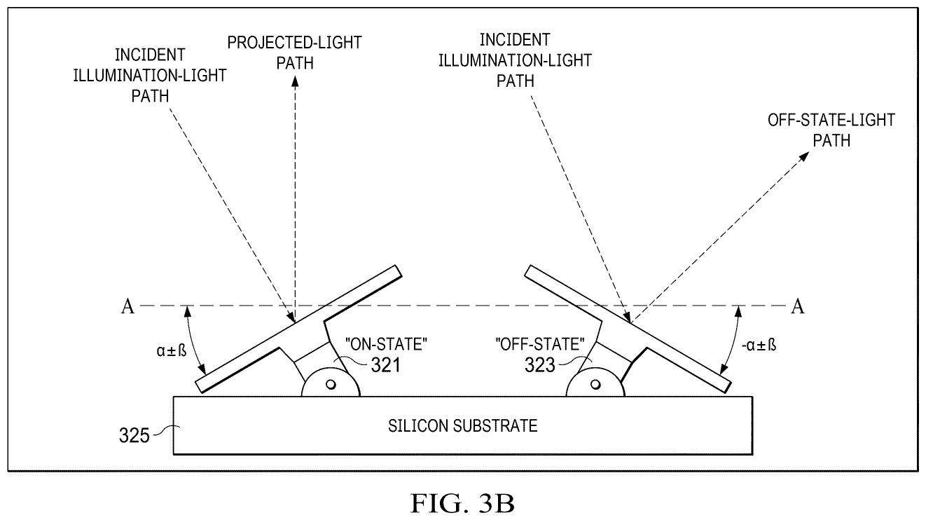

FIGS. 3A and 3B illustrate the operation of a portion 300 of the mirrors 301 in a diamond oriented DMD micromirror array. In FIG. 3A, mirrors 302 are labeled “ON-STATE” MICROMIRRORS and are shown as bright, indicating the light is being projected towards the viewer. Mirrors 303 are labeled “OFF-STATE” MICROMIRRORS” and are shaded dark, indicating the light is being reflected away from the viewer, and into a light trap (not shown in FIG. 3A). Illumination light 304 labeled “LIGHT” enters the array of mirrors 301 from the left side (as oriented in FIG. 3A).

FIG. 3B shows the operation of an “ON-STATE” mirror and an “OFF-STATE” mirror in a cross sectional view taken along line A-A in FIG. 3A. The mirrors 321 and 323 are shown over a silicon substrate 325. Mirror 321 is in the “ON-STATE”, and is tilted to a positive angle +α with a tolerance +/−β. In the example shown in FIG. 3B, α can be 10 degrees, 12 degrees, 14 degrees, 17 degrees or another angle. Light reflected by the “ON-STATE” mirror 321 is directed towards a path designated the “PROJECTED-LIGHT PATH”. Mirror 323 is in the “OFF-STATE”, and is shown tilted to an angle −α+/−β. The illumination light (designated “INCIDENT ILLUMINATION LIGHT PATH”) is then reflected away from the projection light path to the “OFF-STATE-LIGHT PATH”, and to a light trap (not shown). Using DMDs to modulate the intensity of the incident light is a subtractive process; if all of the mirrors in an array are in the ON state for a given display time, all of the incident illumination light is reflected to a projection light path. For any mirrors in the OFF state, the incident illumination light is reflected away from the projection light path. By loading bit map patterns onto the DMD, the intensity of the light is modulated, and images can be projected. Pulse width modulation of the patterns displayed on the DMD can be used to further vary intensity and to vary color intensity when color illumination is used.

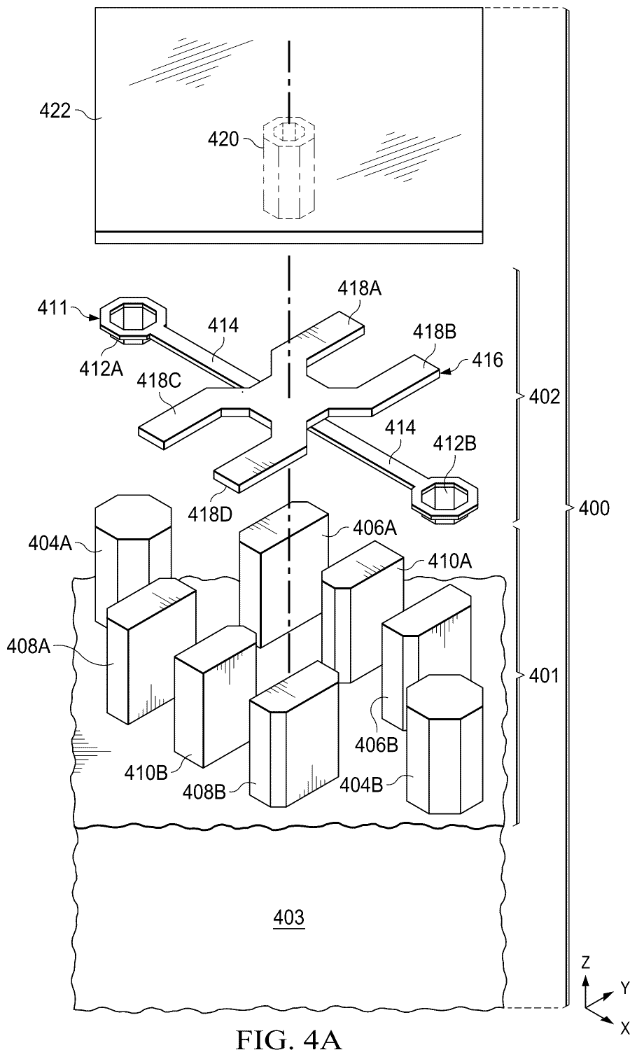

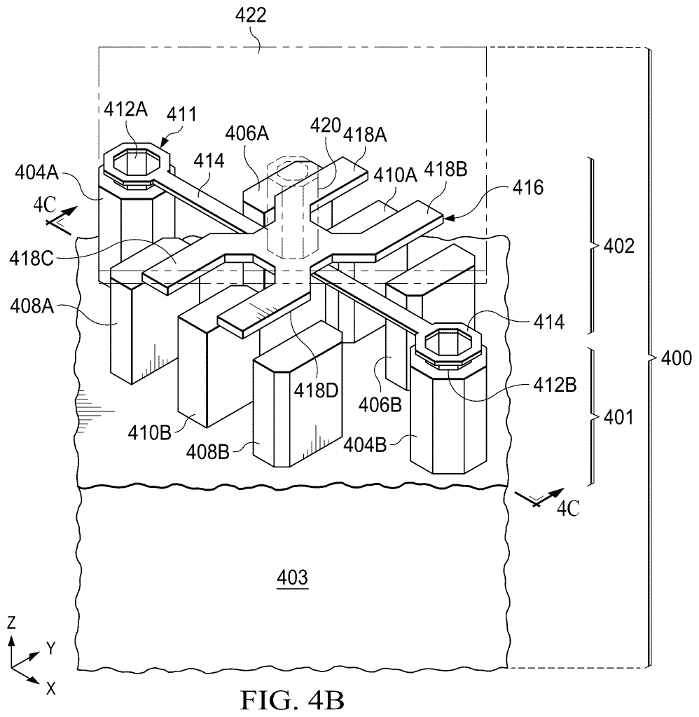

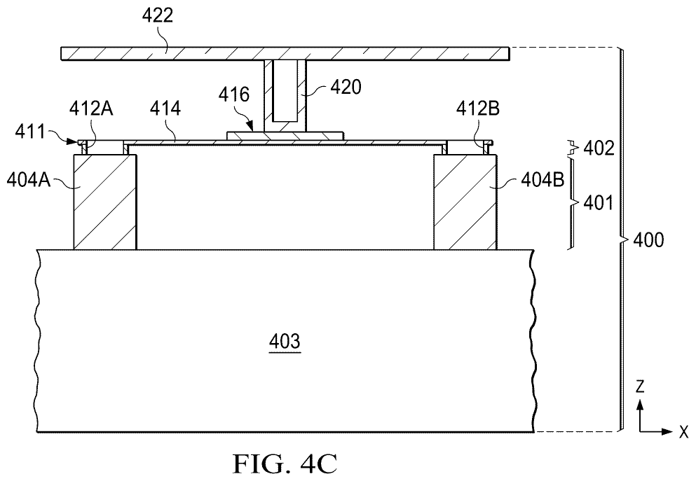

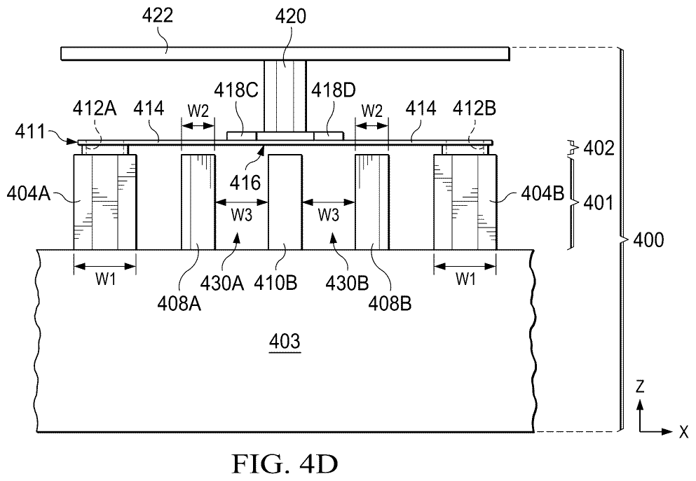

FIG. 4A is an exploded view of a non-contact MEMS device 400 in accordance with various examples. The non-contact MEMS device 400 is an example of a pixel of the pixel array 136 of the SLM 128 in FIG. 1. In the example of FIGS. 4A, the non-contact MEMS device 400 includes a base (sometimes referred to as a substrate herein) 403, an electrode layer 401, a mechanical layer 402, a mirror via 420, and a mirror 422. The mirror via 420 mechanically and electrically couples the mirror 422 to the hinge 411. In some examples, the mirror via 420 has a hollow cylindrical shape or hollow octagonal prism shape. In other examples, the mirror via 420 is a filled via. The substrate 403 includes memory cells (not shown) and electronics to control different states of the non-contact MEMS device 400 responsive to received data. The electrode layer 401 includes hinge electrode pads 404A and 404B, electrodes 406A and 406B, electrodes 408A and 408B, and electrodes 410A and 410B. The mechanical layer 402 includes a hinge 411 with hinge vias 412A and 412B and with extensions 418A to 418D. In some examples, the hinge electrode pads 404A and 404B are made of an M4 deposition layer, and the hinge vias 412A and 412B are made from a spacer layer and hinge pattern and respective deposition layers. In the example of FIG. 4A, the hinge 411 includes a first portion 414 and a second portion 416. The first portion 414 of the hinge 411 extends between the hinge vias 412A and 412B. The second portion 416 of the hinge 411 includes the extensions 418A to 418D. In some examples, the second portion 416 of the hinge 411 is thicker than the first portion 414 of the hinge 411.

FIG. 4B is a perspective view of the non-contact MEMS device 400 of FIG. 4A. In the perspective view of FIG. 4B, the substrate 403, the hinge electrode pads 404A and 404B, the electrodes 406A and 406B, the electrodes 408A and 408B, the electrodes 410A and 410B, the hinge 411, the mirror via 420, the mirror 422, direction X, direction Y, and direction Z are represented. As shown in FIG. 4B, the hinge electrode pads 404A and 404B, the electrodes 406A and 406B, the electrodes 408A and 408B, and the electrodes 410A and 410B are over the substrate 403 in the +Z direction. The hinge via 412A is coupled to the hinge electrode pad 404A physically and electrically. The hinge via 412B is coupled to the hinge electrode pad 404B physically and electrically. The first portion 414 of the hinge 411 extends between the hinge via 412A and the hinge via 412B in the +X direction. The extension 418A of the hinge 411 extends in the Y direction relative to the first portion 414 of the hinge 411 and is over a gap between the electrode 406A and the electrode 410A. The extension 418B of the hinge 411 extends in the Y direction relative to the first portion 414 of the hinge 411 and is over a gap between the electrode 406B and the electrode 410A. The extension 418C of the hinge 411 extends in the −Y direction relative to the first portion 414 of the hinge 411 and is over a gap between the electrode 408A and the electrode 410B. The extension 418D of the hinge 411 extends in the −Y direction relative to the first portion 414 of the hinge 411 and is over a gap between the electrode 408B and the electrode 410B. The mirror via 420 couples the mirror 422 to a center of the hinge 411 (e.g., the center of the second portion 416 of the hinge 411).

FIG. 4C is a cross-sectional view of the non-contact MEMS device 400 of FIG. 4B. In the cross-sectional view of FIG. 4C, the substrate 403, the hinge electrode pads 404A and 404B, the hinge 411, the mirror via 420, the mirror 422, the X direction, and the Z direction are represented. The hinge 411 includes the hinge vias 412A and 412B, the first portion 414 extending between the hinge vias 412A and 412B, and the second portion 416. In some examples as in FIG. 4C, the second portion 416 of the hinge 411 is over the first portion 414 of the hinge 411. In other examples, the second portion 416 of the hinge 411 is under the first portion 414 of the hinge 411. In some examples, the second portion 416 of the hinge 411 is thicker than first portion 414 of the hinge 411. In some examples, the first portion 414 may have a thickness of approximately 20 nm, and the second portion 416 may have a thickness of approximately 50 nm. In other examples, the thickness of the first portion 414 and/or the second portion 416 may vary. In such examples, the thickness (in the Z direction) of the first portion 414 of the hinge 411 is selected so that the first portion 414 has a target flexibility and target durability. Meanwhile, the thickness (in the Z direction) of the second portion 416 of the hinge is selected so that the second portion 416 has a target rigidity.

FIG. 4D is a side view of the non-contact MEMS device of FIG. 4A to 4C. In the side view of FIG. 4D, the substrate 403, the hinge electrode pads 404A and 404B, the electrodes 408A and 408B, the electrode 410B, the hinge 411, the mirror via 420, the mirror 422, the X direction, and the Z direction are represented. The hinge 411 includes the hinge vias 412A and 412B, the first portion 414 extending between the hinge vias 412A and 412B, and the second portion 416. In the example of FIG. 4D, the hinge electrode pads 404A and 404B have more thickness (in the X direction) and have the same height (in the Z direction) compared to the electrodes 408A, 408B, and 410B. In some examples, each of the hinge electrode pads 404A and 404B has a width W1 in the X direction. In some examples, W1 is approximately 0.85 um. Each of the electrodes 408A, 408B, and 410B has a width W2 in the X direction. In some examples, W2 is approximately 0.45 um. As shown, the extension 418C of the hinge 411 is over a gap 430A between the electrodes 408A and 410B. The extension 418D of the hinge 411 is over a gap 430B between the electrodes 408B and 410B. Each of the gaps 430A and 430 has a width W3 in the X direction. In some examples, W3 is approximately 0.80 um. In the example of FIG. 4D, W1, W2, and W3 relate to a pixel size of 5 μm. In other examples, pixel sizes that use the MEMS devices described herein may vary between 3 μm to 10 μm. For each pixel size, W1, W2, and W3 may vary.

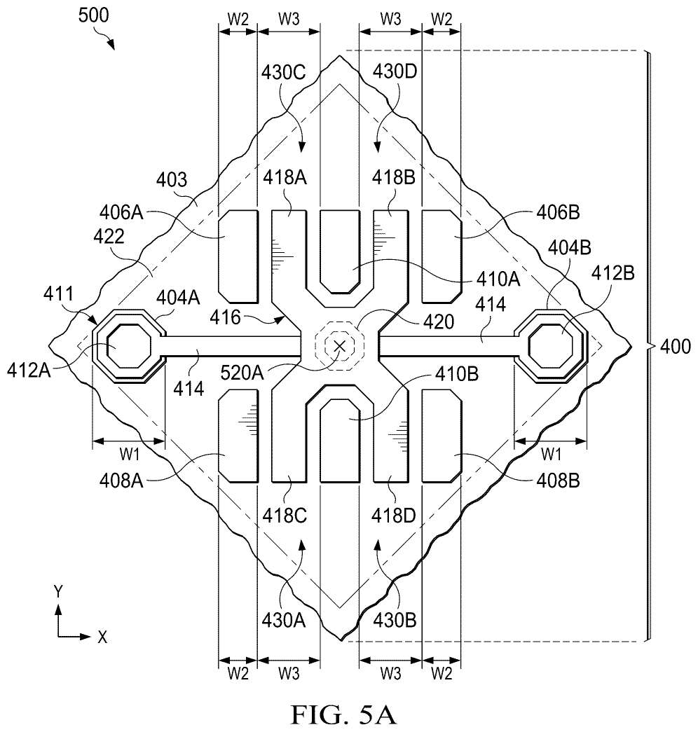

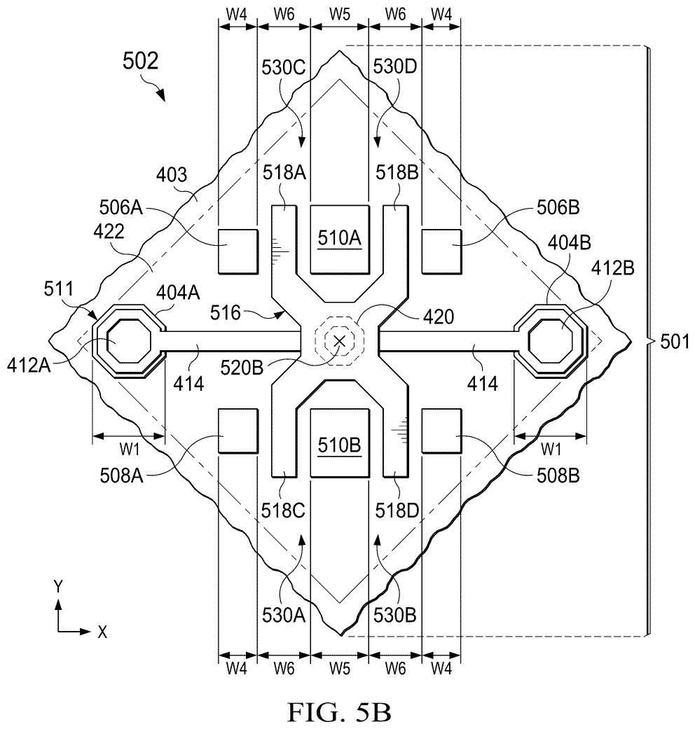

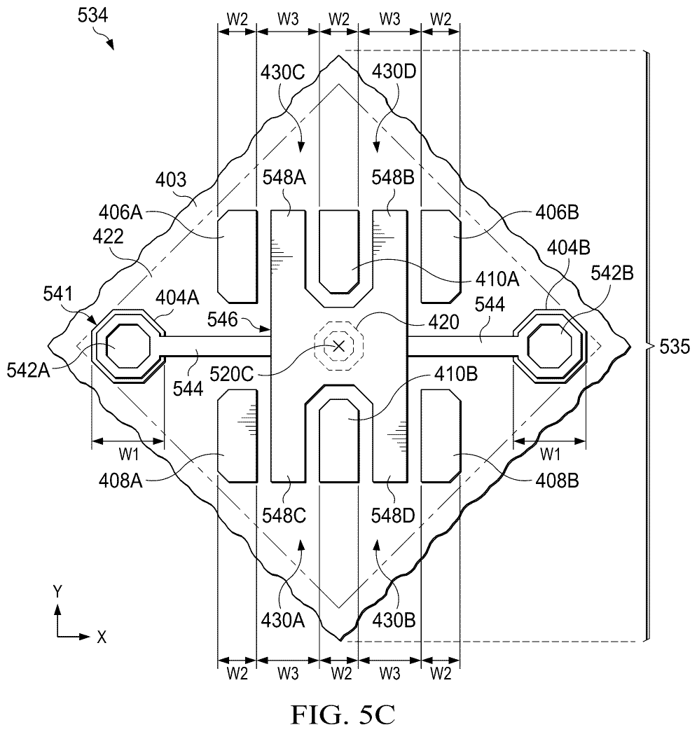

FIG. 5A is a see-through top view 500 of the non-contact MEMS device 400 of FIGS. 4A to 4D. In the see-through top view 500 of FIG. 5A, the substrate 403, the hinge 411, the hinge electrode pads 404A and 404B, the electrodes 406A and 406B, the electrodes 408A and 408B, the electrodes 410A and 410B, the mirror via 420, the mirror 422, the X direction, the Y direction, a center point 520A, gaps 430A to 430D, and widths W1, W2, and W3 are represented. The hinge 411 includes the hinge vias 412A and 412B, the first portion 414, and the second portion 416. The center point 520A is at the center of the MEMS device 400 or the second portion 416 of the hinge 411 in the XY plane represented in FIG. 5A. In the example of FIG. 5A, the mirror via 420 has a hollow octagonal shape centered around center point 520A.

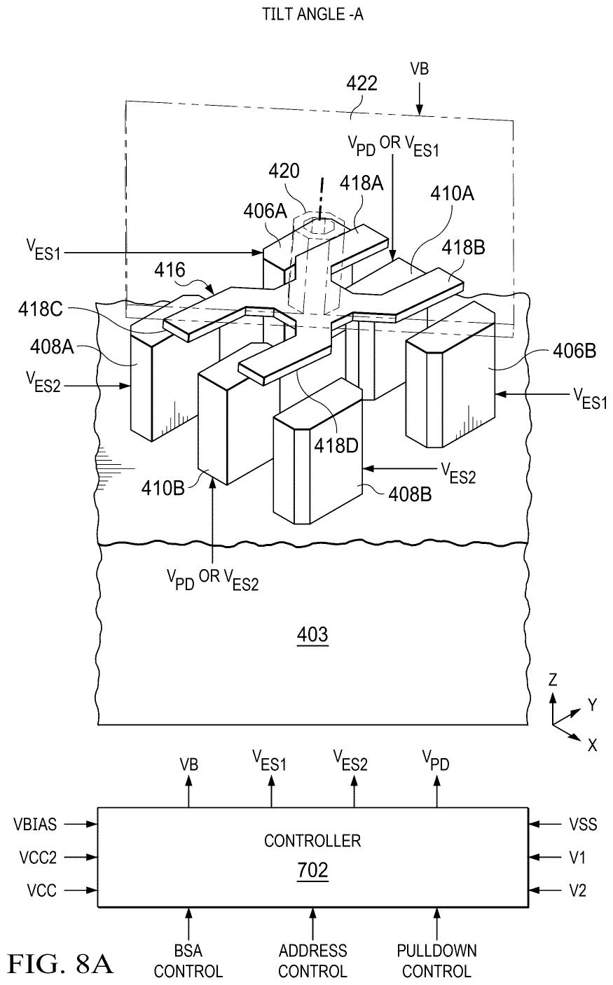

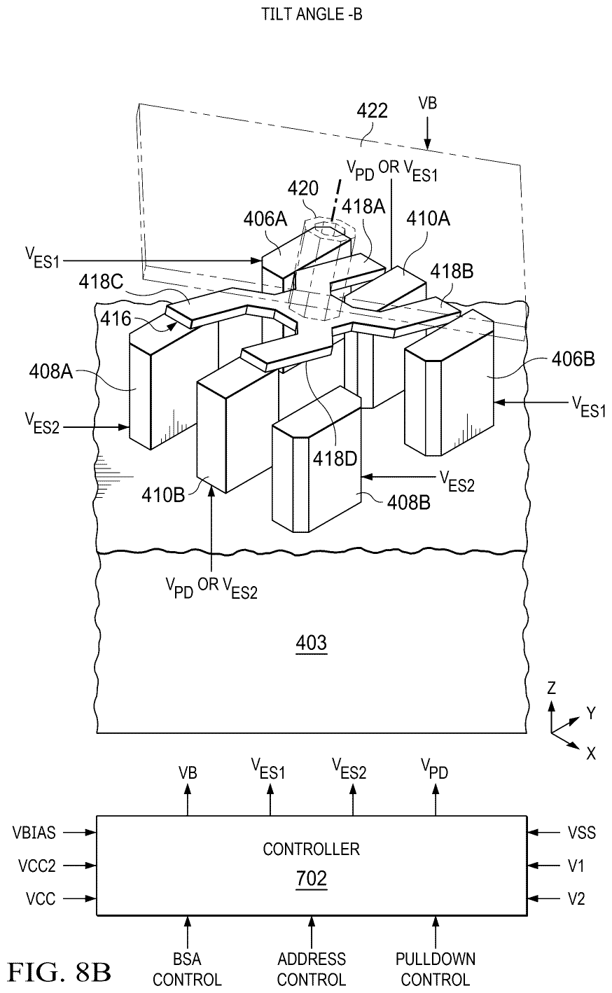

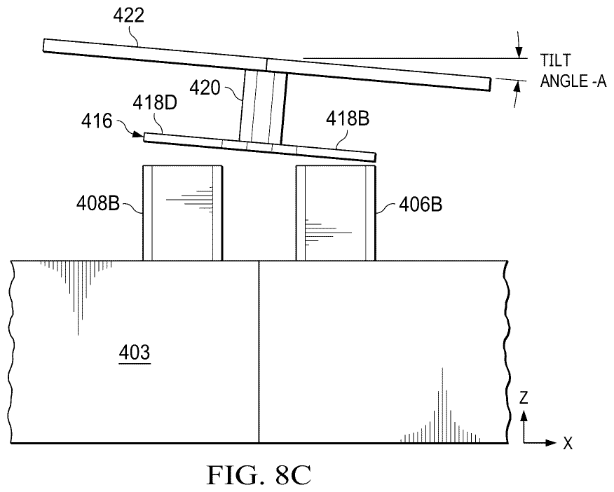

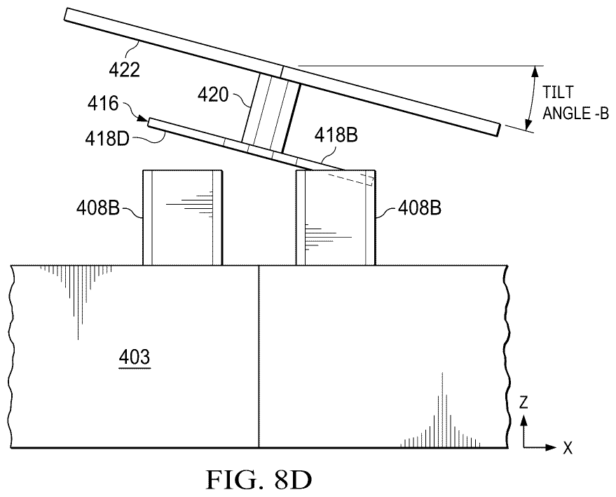

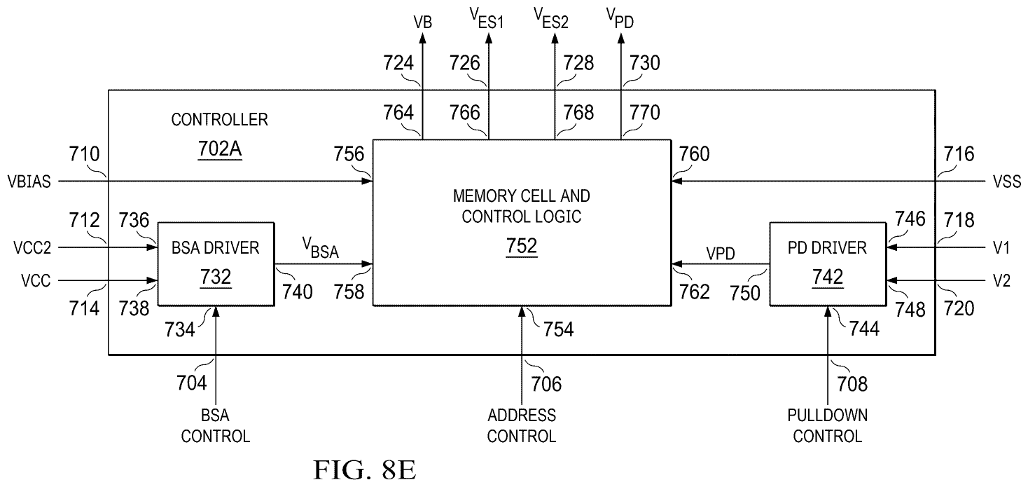

The second portion 416 of the hinge 411 has an X shape and includes extensions 418A to 418D. In the example of FIG. 5A, the extension 418A is an upper left extension from the center point 520A or center shape (e.g., a central square, a central rectangle, a central an octagon, or other shape) of the second portion 416 of the hinge 411. The extension 418A: initially extend diagonally (e.g., at an angle of 135° from the center point 520A or center shape) in a −X direction and a +Y direction relative to the center point 520A or center shape; and then extends vertically in a +Y direction relative to its diagonal portion. The vertical portion of the extension 418A extends over a gap 430C (with width W3 in the X direction) between the electrode 406A and the electrode 410A. The width of the vertical portion of the extension 418A is less than the width W3 of the gap 430C so that the vertical portion of the extension 418A does not physically contact the electrodes 406A and 410A when rotating into the gap 430C (e.g., as in FIGS. 8B and 8D).

The extension 418B is an upper right extension from the center point 520A or center shape of the second portion 416 of the hinge 411. The extension 418B: initially extends diagonally (e.g., at an angle of 45° from the center point 520A or center shape) in a +X direction and a +Y direction relative to the center point 520A; and then extends vertically in a +Y direction relative to its diagonal portion. The vertical portion of the extension 418B extends over a gap 430D (with width W3 in the X direction) between electrode 406B and the electrode 410A. The width of the vertical portion of the extension 418B is less than width W3 of the gap 430D so that the vertical portion of the extension 418B does not physically contact the electrodes 406B and 410A when rotating into the gap 430D (e.g., as in FIGS. 8B and 8D).

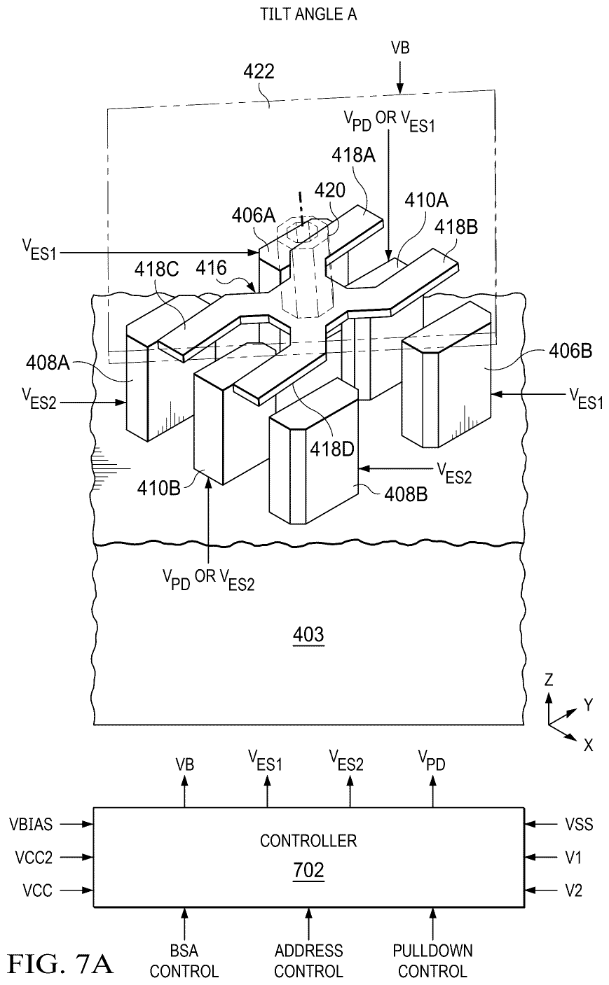

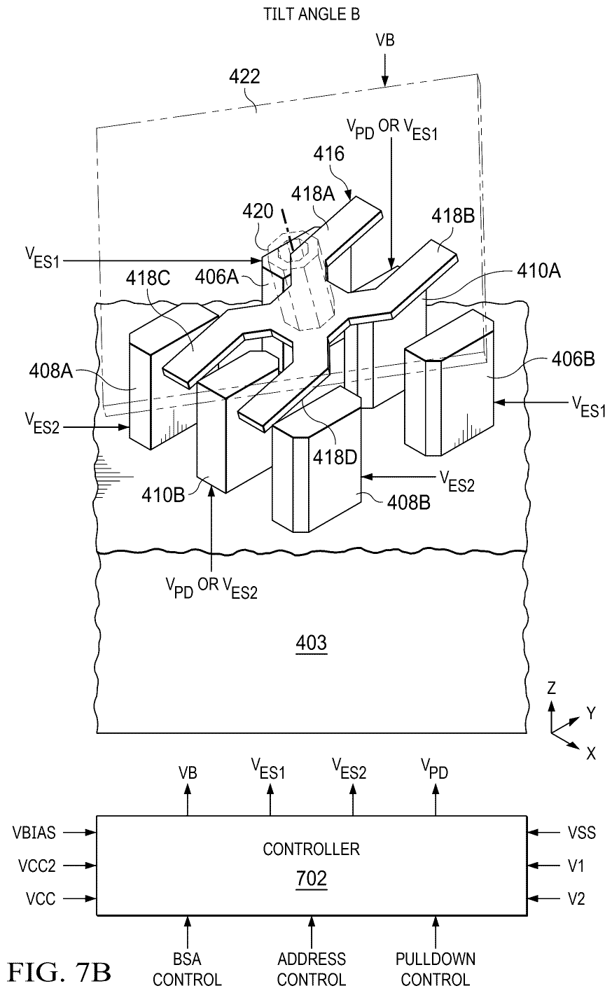

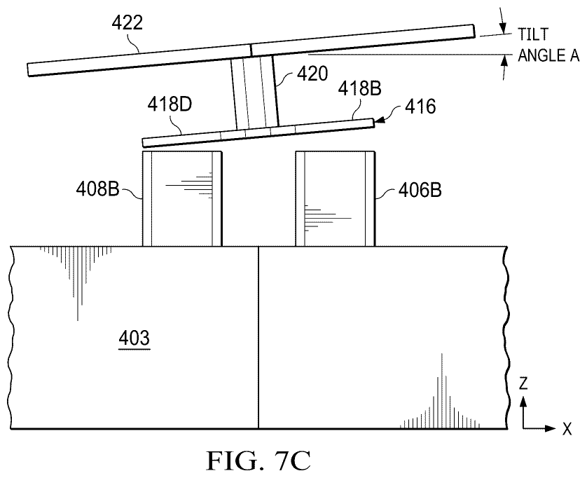

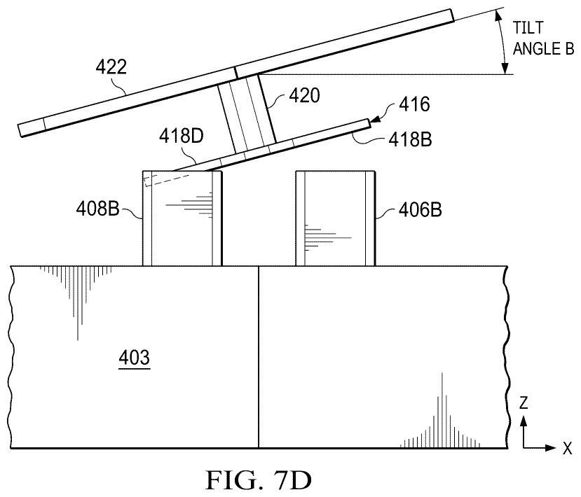

The extension 418C is a lower left extension from the center point 520A or center shape of the second portion 416 of the hinge 411. The extension 418C: initially extends diagonally (e.g., at an angle of −135° from the center point 520A or center shape) in the −X direction and −Y direction relative to the center point 520A or center shape; and then extends vertically in the −Y direction relative to its diagonal portion. The vertical portion of the extension 418C extends over the gap 430A (with width W3 in the X direction) between the electrode 408A and the electrode 410B. The width of the vertical portion of the extension 418C is less than the width W3 of the gap 430A so that the vertical portion of the extension 418C does not physically contact the electrodes 408A and 410B when rotating (e.g., as in FIGS. 7B and 7D).

The extension 418D is a lower right extension from the center point 520A or the center shape of the second portion 416 of the hinge 411. The extension 418D: initially extends diagonally (e.g., at an angle of −45° from the center point 520A or center shape) in the +X direction and −Y direction relative to the center point 520A or center shape; and then extends vertically in the −Y direction relative to its diagonal portion. The vertical portion of the extension 418D extends over the gap 430A (with width W3 in the X direction) between the electrode 408B and the electrode 410B. The width of the vertical portion of the extension 418D is less than the width W3 of the gap 430B so that the vertical portion of the extension 418D does not physically contact electrodes 408B and 410B when rotating (e.g., as in FIGS. 7B and 7D).

In the example of FIG. 5A, the second portion 416 of the hinge 411 has an X shape. In other examples, a second portion of a hinge may have another shape. In one example, a second portion of a hinge has an X shape with thinner vertical portions (as in FIG. 5B) compared to the X shape in FIG. 5A. In another example, a second portion of a hinge has a H shape (as in FIG. 5C) instead of an X shape.

In some examples, the extension 418A: is spaced evenly between the electrode 406A and the electrode 410A; and is aligned lengthwise with the electrodes 406A and 410A in the Y direction. The extension 418B: is spaced evenly between the electrode 406B and the electrode 410A; and is aligned lengthwise with the electrodes 406B and 410A in the Y direction. The extension 418C: is spaced evenly between the electrode 408A and the electrode 410B; and is aligned lengthwise with the electrodes 408A and 410B in the −Y direction. The extension 418D: is spaced evenly between the electrode 408B and the electrode 410B; and is aligned lengthwise with the electrodes 408B and 410B in the −Y direction. In the example of FIG. 5A, the dimensions of the mirror 422 cover the hinge 411 and the electrodes 406A, 406B, 408A, 408B, 410A, and 410B.

FIG. 5B is a see-through top view 502 of another non-contact MEMS device 501. In the see-through top view 502 of the non-contact MEMS device 501, the substrate 403, a hinge 511, the hinge electrode pads 404A and 404B, electrodes 506A and 506B, electrodes 508A and 508B, electrodes 510A and 510B, the mirror via 420, the mirror 422, the X direction, the Y direction, gaps 530A to 530D, and widths W1, W4, W5, and W6 are represented. The hinge 511 includes the hinge vias 412A and 412B, the first portion 414, and a second portion 516. The second portion 516 of the hinge 511 includes extensions 518A to 518D. The center point 520B is at the center of the MEMS device 501 or the second portion 516 of the hinge 511 in the XY plane represented in FIG. 5B. In the example of FIG. 5B, the mirror via 420 has a hollow octagonal shape centered around center point 520B.

In the example of FIG. 5B, the second portion 516 of the hinge 511 has an X shape and includes extensions 518A to 518D. The extension 518A is an upper left extension from the center point 520B or center shape (e.g., a central square, a central rectangle, a central octagon, or other shape) of the second portion 516 of the hinge 511. The extension 518A: initially extend diagonally (e.g., at an angle of 135° from the center point 520B or center shape) in a −X direction and a +Y direction relative to the center point 520B or center shape; and then extends vertically in a +Y direction relative to its diagonal portion. The vertical portion of the extension 518A extends over a gap 530C (with width W6 in the X direction) between the electrode 506A and the electrode 510A. The width of the vertical portion of the extension 518A is less than the width W6 of the gap 530C so that the vertical portion of the extension 518A does not physically contact the electrodes 506A and 510A when rotating into the gap 530C (e.g., similar to FIGS. 8B and 8D).

The extension 518B is an upper right extension from the center point 520B or center shape of the second portion 516 of the hinge 511. The extension 518B: initially extends diagonally (e.g., at an angle of 45° from the center point 520B or center shape) in a +X direction and a +Y direction relative to the center point 520B; and then extends vertically in a +Y direction relative to its diagonal portion. The vertical portion of the extension 518B extends over a gap 530D (with width W6 in the X direction) between the electrode 506B and the electrode 510A. The width of the vertical portion of the extension 518B is less than the width W6 of the gap 530D so that the vertical portion of the extension 518B does not physically contact the electrodes 506B and 510A when rotating into the gap 530D (e.g., similar to FIGS. 8B and 8D).

The extension 518C is a lower left extension from the center point 520B or center shape of the second portion 516 of the hinge 511. The extension 518C: initially extends diagonally (e.g., at an angle of −135° from the center point 520B or center shape) in the −X direction and −Y direction relative to the center point 520B or center shape; and then extends vertically in the −Y direction relative to its diagonal portion. The vertical portion of the extension 518C extends over a gap 530A (with width W6 in the X direction) between the electrode 508A and the electrode 510B. The width of the vertical portion of the extension 518C is less than the width W6 of the gap 530A so that the vertical portion of the extension 518C does not physically contact the electrodes 508A and 510B when rotating into the gap 530A (e.g., similar to FIGS. 7B and 7D).

The extension 518D is a lower right extension from the center point 520B or the center shape of the second portion 516 of the hinge 511. The extension 518D: initially extends diagonally (e.g., at an angle of −45° from the center point 520B or center shape) in the +X direction and −Y direction relative to the center point 520B or center shape; and then extends vertically in the −Y direction relative to its diagonal portion. The vertical portion of the extension 518D extends over a gap 530B (with width W6 in the X direction) between the electrode 508B and the electrode 510B. The width of the vertical portion of the extension 518D is less than the width W6 of the gap 530A so that the vertical portion of the extension 518D does not physically contact the electrodes 508B and 510B when rotating into the gap 530B (e.g., similar to FIGS. 7B and 7D).

In the example of FIG. 5B, the diagonal portions of the second portion 516 of the hinge 511 are approximately the same as the diagonal portions of the second portion 416 of the hinge 411. The vertical portions of the second portion 516 of the hinge 511 are less wide than the vertical portions of the second portion 416 of the hinge 411 in FIG. 5A. For example, if each of the vertical portions of the second portion 416 of the hinge 411 has a width W2 in the X direction, each of the vertical portions of the second portion 516 of the hinge 511 has a width less than W2 in the X direction. Also, in some examples as in FIG. 5B, the electrodes 506A, 506B, 508A, and 508B have: the same width as the electrodes 510A and 510B in the X direction; and less length than the electrodes 510A and 510B in the Y direction. Both the MEMS device 400 in FIG. 5A and the MEMS device 501 of FIG. 5B are acceptable designs with the MEMS device 400 being easier to manufacture due to the layout of the electrodes 406A, 406B, 408A, 408B, 410A, 410B being more uniform for the MEMS device 400 compared to the layout of the electrodes 506A, 506B, 508A, 508B, 510A, 510B for the MEMS device 501.

In some examples, the extension 518A: is spaced evenly between the electrode 506A and the electrode 510A; extends beyond the electrode 506A in the Y direction; and is aligned lengthwise with the electrode 510A in the Y direction. The extension 518B: is spaced evenly between the electrode 506B and the electrode 510A; extends beyond the electrode 506B in the Y direction and is aligned lengthwise with the electrode 510A in the Y direction. The extension 518C: is spaced evenly between the electrode 508A and the electrode 510B; extends beyond the electrode 508A in the −Y direction; and is aligned lengthwise with the electrode 510B in the −Y direction. The extension 518D: is spaced evenly between the electrode 508B and the electrode 510B; extends beyond the electrode 508B in the −Y direction; and is aligned lengthwise with the electrode 510B in the −Y direction. In the example of FIG. 5B, the dimensions of the mirror 422 cover the hinge 511 and the electrodes 506A, 506B, 508A, 508B, 510A, and 510B.

FIG. 5C is a see-through top view 534 of a non-contact MEMS device 535. In the see-through top view 534 of FIG. 5C, the substrate 403, a hinge 541, the hinge electrode pads 404A and 404B, the electrodes 406A and 406B, the electrodes 408A and 408B, the electrodes 410A and 410B, the mirror via 420, the mirror 422, the X direction, the Y direction, a center point 520C, gaps 430A to 430D, and widths W1, W2, and W3 are represented. The hinge 511 includes the hinge vias 542A and 542B, a first portion 544, and a second portion 546. The center point 520C is at the center of the MEMS device 535 or the second portion 546 of the hinge 541 in the XY plane represented in FIG. 5C. In the example of FIG. 5C, the mirror via 420 has a hollow octagonal shape centered around center point 520C.

In the example of FIG. 5C, the second portion 546 of the hinge 541 has an H shape and includes extensions 548A to 548D. The extension 548A is an upper left extension from the center shape (e.g., a central square or central rectangle) of the second portion 546 of the hinge 541. The extension 548A extends vertically in +Y direction from an upper left region of the center shape. The extension 548A extends over the gap 430C (with width W3 in the X direction) between the electrode 406A and the electrode 410A. The width of the extension 548A is less than the width W3 of the gap 430C so that the extension 548A does not physically contact the electrodes 406A and 410A when rotating into the gap 430C (e.g., similar to FIGS. 8B and 8D).

The extension 548B is an upper right extension from the center shape of the second portion 546 of the hinge 541. The extension 548B extends in a +Y direction from an upper right region of the center shape. The extension 548B extends over the gap 430D (with width W3 in the X direction) between the electrode 406B and the electrode 410A. The width of the extension 548B is less than the width W3 of the gap 430C so that the extension 548B does not physically contact the electrodes 406B and 410A when rotating into the gap 430D (e.g., similar to FIGS. 8B and 8D).

The extension 548C is a lower left extension from the center shape of the second portion 546 of the hinge 541. The extension 548C extends in a −Y direction from lower left region of the center shape. The extension 548C extends over the gap 430A (with width W3 in the X direction) between the electrode 408A and the electrode 410B. The width of the extension 548C is less than the width W3 of the gap 430A so that the extension 548C does not physically contact the electrodes 408A and 410B when rotating into the gap 430A (e.g., similar to FIGS. 7B and 7D).

The extension 548D is a lower right extension from the center shape of the second portion 546 of the hinge 541. The extension 548D extends in a −Y direction from lower right region of the center shape. The extension 548D extends over the gap 430B (with width W3 in the X direction) between the electrode 408B and the electrode 410B. The width of the extension 548D is less than the width W3 of the gap 430B so that the extension 548D does not physically contact the electrodes 408B and 410B when rotating into the gap 430B (e.g., similar to FIGS. 7B and 7D).

In the example of FIG. 5C, each of the extensions 548A to 548D of the second portion 546 of the hinge 541 has the same width as each of the vertical portions of the extensions 418A to 418D of the second portion 416 of the hinge 411 in FIG. 5A. An example width in the X direction for each of the extensions 548A to 548D is the width W2. The MEMS device 535 is another acceptable design with a layout similar to the layout of the MEMS device 400.

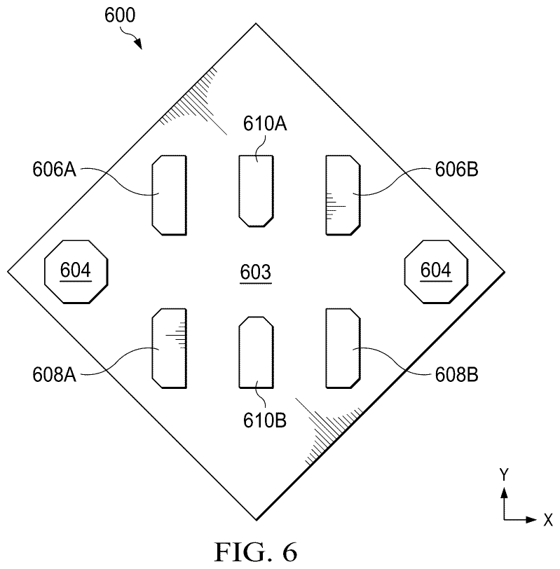

FIG. 6 is a top view of an electrode layer 600 for a non-contact MEMS device in accordance with various examples. The electrode layer 600 is an example of the electrode layer 401 in FIG. 4A. In the example of FIG. 6, the electrode layer 600 is over a substrate 603 and includes hinge electrode pads 604, electrode 606A and 606B, electrodes 608A and 608B, and electrodes 610A and 610B. In some examples, the electrodes 606A, 610A, and 606B are controlled together as a first electrode group (e.g., first control voltages are applied to the first electrode group to vary the position of a related mirror). In such examples, the electrodes 608A, 610B, and 608B are controlled together as a second electrode group (e.g., second control voltages are applied to the second electrode group to vary the position of a related mirror). In other examples, the electrodes 606A and 606B are controlled together as a first electrode group (e.g., first control voltages are applied to the first electrode group to vary the position of a related mirror), the electrode 608A and 608B are controlled together as a second electrode group (e.g., second control voltages are applied to the second electrode group to vary the position of a related mirror), and the electrodes 610A and 610B are controlled together as a third electrode group (e.g., third control voltages are applied to the third electrode group to vary the position of a related mirror).

In the example of FIG. 6, each of the electrodes 606A and 606B has a rectangular prism shape with left corners (in the −X direction) cut. Each of the electrodes 608A and 608B has a rectangular prism shape with right corners (in the X direction) cut. In such examples, cut corners for electrodes may be used to ensure a minimum gap between adjacent electrodes (same pixel or adjacent pixel) and/or to ensure electrode layer components fit in the space below the related mirror. The electrode 610A has a rectangular prism shape with lower corners (in the −Y direction) cut. The electrode 610A has a rectangular prism shape with upper corners (in the Y direction) cut. With lower corners cut for the rectangular prism shape of the electrode 610A and upper corners cut for the rectangular prism shape of the electrode 610B, a target spacing between the X shape for the second portion of a hinge (e.g., the second portion 416 of the hinge 411 in FIGS. 4A, 4B, and 5A, or the second portion 516 of the hinge 511 in FIG. 5B) is accommodated. Each of the hinge electrode pads 604 have a solid octagonal prism shape. In some examples, a control voltage may be applied to the hinge electrode pads 604 to vary the position of a related mirror, where the control voltage is applied via the hinge electrode pads 604 to a related hinge, mirror via, and mirror. In other examples, the shape of the hinge electrode pads 604, the electrodes 606A and 606B, the electrodes 608A and 608B, and the electrodes 610A and 610B may vary subject to layout rules for minimum width, spacing, etc.). Example alternative shapes for electrodes include cylindrical shape, an octagonal prism shape, or a rectangular prism shape with uncut corners.

FIGS. 7A and 7B are perspective views of some of the non-contact MEMS device 400 of FIGS. 4A to 4D and a controller 702 in accordance with various examples. In the perspective views of FIGS. 7A and 7B, the electrodes 404A and 404B, the hinge vias 412A and 412B, and the first portion 414 of the hinge 411 are omitted from the views for convenience to focus attention to the position of the second portion 416 of the hinge 411 relative to the electrodes 406A, 406B, 408A, 408B, 410A, and 410B and related control options for the different tilt angles represented.

In some examples, the MEMS device 400 and the controller 702 may be part of a DMD that includes many MEMS devices and respective controllers. Each such controller (e.g., the controller 702) is configured to: receive input control signals; receive input voltages; and provide control voltages to respective electrodes of a MEMS device. In some examples, the input control signals include: a block stepped address (BSA) control signal; an address control signal; and a pulldown control signal. The input control signals may be provided, for example, by a DMD controller (e.g., controller 102 in FIG. 1) separate from the DMD (e.g., SLM 128 in FIG. 1). In some examples, the input voltages received by the controller 702 include: a bias voltage (VBIAS); a first power supply voltage (VCC2), a second power supply voltage (VCC); a ground voltage (VSS); a first pulldown voltage value (V1); and a second pulldown voltage value (V2). Such voltages may be generated locally by voltage sources included with or coupled to a DMD.

In some examples, the control voltages provided by the controller 702 include a mirror bias voltage level VB, voltage levels V_{ES1}, voltage levels V_{ES2}, and pulldown voltage levels V_{PD}. VB is provided to the mirror 422 (e.g., via the hinge electrode pad 404A and/or 404B, the hinge 411, and the mirror via 420). V_{ES1} is provided to electrodes 406A and 406B (sometimes referred to as a first set of electrodes or positive side electrodes herein). V_{ES2} is provided to the electrodes 408A and 408B (sometimes referred to as a second set of electrodes or negative side electrodes herein). V_{PD} is applied to the electrodes 410A and 410B. In other examples, V_{PD} is not used. In such examples, the pulldown control data, V1, V2, and V_{PD} may be omitted. In some examples, V_{ES1} may be provided to the electrode 410A instead of V_{PD}, and V_{ES2} may be provided to the electrode 410B instead of V_{PD}.

With the controller 702 and related inputs/outputs, the controller 702 is able to set the mirror 422 to different positions. Example positions include: a preliminary on position (e.g., tilt angle A herein); a target on position (e.g., tilt angle B herein); a preliminary off position (e.g., tilt angle −A herein); and a target off position (e.g., tilt angle −B herein).

In the example of FIG. 7A, the controller 702 sets the mirror 422 to the preliminary on position (tilt angle A) responsive to input control signals (e.g., the BSA control signal, the address control signal, and the pulldown control signal if used) and application of V_{ES1}, V_{ES2}, VB, and V_{PD} (if used) to respective electrodes. FIG. 7C is a side view of some of the non-contact MEMS device 400 of FIGS. 4A to 4D with the mirror 422 set to the preliminary on position or tilt angle A. In the side view of FIG. 7C, the electrode 404B, the hinge via 412B, and the first portion 414 of the hinge 411 are omitted from the view for convenience to focus attention to the position of the extensions 418B and 418B of the second portion 416 of the hinge 411 relative to the electrodes 406B and 408B for the tilt angle represented. In some examples, the tilt angle A is +5 degrees. In other examples, the tilt angle A may be another angle (e.g., +5 to +10 degrees). With tilt angle A, the MEMS device mirror tilt is preconditioned in a target direction to facilitate transition to a target on position (e.g., tilt angle B herein).

In the example of FIG. 7B, the controller 702 sets the mirror 422 to the target on position (tilt angle B) responsive to the input control signals (e.g., the BSA control signal, the address control signal, and the pulldown control signal if used) and application of V_{ES1}, V_{ES2}, VB, and V_{PD} (if used) to respective electrodes. FIG. 7D is a side view of some of the non-contact MEMS device 400 of FIGS. 4A to 4D with the mirror 422 set to the target on position or tilt angle B. In the side view of FIG. 7D, the electrode 404B, the hinge via 412B, and the first portion 414 of the hinge 411 are omitted from the view for convenience to focus attention to the position of the extensions 418B and 418B of the second portion 416 of the hinge 411 relative to the electrodes 406B and 408B for the tilt angle represented. In some examples, the tilt angle B is +15 degrees. In other examples, the tilt angle B may be another angle (e.g., +20 degrees or another angle).

FIGS. 8A and 8B are perspective views of some of the non-contact MEMS device 400 of FIGS. 4A to 4D and the controller 702 in accordance with various examples. In the perspective views of FIGS. 8A and BB, the electrodes 404A and 404B, the hinge vias 412A and 412B, and the first portion 414 of the hinge 411 are omitted from the views for convenience to focus attention to the position of the second portion 416 of the hinge 411 relative to the electrodes 406A, 406B, 408A, 408B, 410A, and 410B and related control options for the different tilt angles represented.

In the example of FIG. 8A, the controller 702 sets the mirror 422 to a preliminary off position (tilt angle −A) responsive to input control signals (e.g., the BSA control signal, the address control signal, and the pulldown control signal if used) and application of V_{ES1}, V_{ES2}, VB, and V_{PD} (if used) to respective electrodes. FIG. 8C is a side view of some of the non-contact MEMS device 400 of FIGS. 4A to 4D with the mirror 422 set to the preliminary off position or tilt angle −A. In the side view of FIG. 8C, the electrode 404B, the hinge via 412B, and the first portion 414 of the hinge 411 are omitted from the view for convenience to focus attention to the position of the extensions 418B and 418B of the second portion 416 of the hinge 411 relative to the electrodes 406B and 408B for the tilt angle represented. In some examples, the tilt angle −A is −5 degrees. In other examples, the tilt angle −A may be another angle (e.g., −5 to −10 degrees). With tilt angle −A, the MEMS device mirror tilt is preconditioned in a target direction to facilitate transition to a target off position (e.g., tilt angle −B herein).

In the example of FIG. 8B, the controller 702 sets the mirror 422 to the target off position (tilt angle −B) responsive to input control signals (e.g., the BSA control signal, the address control signal, and the pulldown control signal if used) and application of V_{ES1}, V_{ES2}, VB, and V_{PD} (if used) to respective electrodes. FIG. 8D is a side view of some of the non-contact MEMS device 400 of FIGS. 4A to 4D with the target off position. In the side view of FIG. 8D, the electrode 404B, the hinge via 412B, and the first portion 414 of the hinge 411 are omitted from the view for convenience to focus attention to the position of the extensions 418B and 418B of the second portion 416 of the hinge 411 relative to the electrodes 406B and 408B for the tilt angle represented. In some examples, the tilt angle −B is −15 degrees. In other examples, the tilt angle −B may be another angle (e.g., −20 degrees or another angle). In other examples, the relative position of system components (e.g., the light source 120 in FIGS. 1 and 2, the light trap 211 in FIG. 2, and/or the projection aperture 138 in FIGS. 1 and 2) may vary such that the preliminary on/on positions and the target on/off positions may vary or even be swapped (i.e., a +5° tilt angle may be a preliminary off position, a +15° tilt angle may be a target off position, a −5° tilt angle may be a preliminary on position, and a −15° tilt angle may be a target on position).

FIG. 8E is a block diagram of a controller 702A in accordance with various examples. The controller 702A is an example of the controller 702 in FIGS. 7A, 7B, 8A, and 8B. In the example of FIG. 8E, the controller 702A has a first terminal 704, a second terminal 706, a third terminal 708, a fourth terminal 710, a fifth terminal 712, a sixth terminal 714, a seventh terminal 716, an eighth terminal 718, a ninth terminal 720, a tenth terminal 724, an eleventh terminal 726, a twelfth terminal 728, and a thirteenth terminal 730. In the example of FIG. 7E, the controller 702A includes a BSA driver 732, a pulldown (PD) driver 742, and memory cell and control logic 752. In some examples, the memory cell and control logic 752 includes 5-transistor Static Random Access Memory (5T SRAM). The BSA driver 732 has a first terminal 734, a second terminal 736, a third terminal 738, and a fourth terminal 740. The pulldown driver 742 has a first terminal 744, a second terminal 746, a third terminal 748, and a fourth terminal 750. The memory cell and control logic 752 has a first terminal 754, a second terminal 756, a third terminal 758, a fourth terminal 760, a fifth terminal 762, a sixth terminal 764, a seventh terminal 766, an eighth terminal 768, and a ninth terminal 770.

The first terminal 704 of the controller 702A is coupled to the first terminal 734. The second terminal 706 of the controller 702A is coupled to the first terminal 754 of the memory cell and control logic 752. The third terminal 708 of the controller 702A is coupled to the first terminal 744 of the pulldown driver 742. The fourth terminal 710 of the controller 702A is coupled to the second terminal 756 of the memory cell and control logic 752. The fifth terminal 712 of the controller 702A is coupled to the second terminal 736 of the BSA driver 732. The sixth terminal 714 of the controller 702A is coupled to the third terminal 738 of the BSA driver 732. The seventh terminal 716 of the controller 702A is coupled to the fourth terminal 760 of the memory cell and control logic 752. The eighth terminal 718 of the controller 702A is coupled to the second terminal 746 of the pulldown driver 742. The ninth terminal 720 of the controller 702A is coupled to the third terminal 748 of the pulldown driver 742. The tenth terminal 724 of the controller 702A is coupled to the sixth terminal 764 of the memory cell and control logic 752. The eleventh terminal 726 of the controller 702A is coupled to the seventh terminal 766 of the memory cell and control logic 752. The twelfth terminal 728 of the controller 702A is coupled to the is coupled to the eighth terminal 768 of the memory cell and control logic 752. The thirteenth terminal 730 of the controller 702A is coupled to the ninth terminal 770 of the memory.

In some examples, the controller 702A includes buffer/driver circuitry, logic gates, memory cells, and/or latches that operate to: receive input control signals (e.g., the BSA control signal is received at the first terminal 704 and the address control signal is received at the second terminal 706); receive input voltages (e.g., VBIAS is received at the fourth terminal 710, VCC2 is received at the fifth terminal 712, VCC is received at the sixth terminal 714, and VSS is received at the seventh terminal 716); and provide control voltages (e.g., VB is provided at the tenth terminal 724, V_{ES1} is provided at the eleventh terminal 726, and V_{ES2} is provided at the twelfth terminal 728) responsive to the input control signals and the input voltages. In some examples, the controller 702A includes buffer/driver circuitry, logic gates, memory cells, and/or latches that operate to: receive input control signals (e.g., the BSA control signal is received at the first terminal 704, the address control signal is received at the second terminal 706, and the pulldown control signal is received at the third terminal 708); receive input voltages (e.g., VBIAS is received at the fourth terminal 710, VCC2 is received at the fifth terminal 712, VCC is received at the sixth terminal 714, VSS is received at the seventh terminal 716, V1 (e.g., −10V) is received at the eighth terminal 718, and V2 (e.g., 0V) is received at the ninth terminal 720); and provide control voltages (e.g., VB is provided at the tenth terminal 724, V_{ES1} is provided at the eleventh terminal 726, V_{ES2} is provided at the twelfth terminal 728, and V_{PD} is provided at the thirteenth terminal 730) responsive to the input control signals and the input voltages. With the controller 702A, input voltages are selectively forwarded or buffered as control voltages responsive to input control signals.

In some examples, the BSA driver 732 includes buffer circuitry, logic gates, and/or latches that operate to: receive the BSA control signal at the first terminal 734; receive VCC2 at the second terminal 736; receive VCC at the third terminal 738; and provide BSA voltage levels V_{BSA} at the fourth terminal 740 responsive to the BSA control signal, VCC2, and VCC. In the example of FIG. 8E, V_{BSA} is an internal signal used by the controller 702A to adjust V_{ES1} and/or V_{ES2} responsive to V_{BSA}. If V_{BSA} has a first state, V_{ES1} and/or V_{ES2} can be VCC or VSS. If V_{BSA} has a second state, V_{ES1} and/or V_{ES2} can be VCC2 or VCC.

In some examples, the pulldown driver 742 buffer circuitry, logic gates, and/or latches that operate to: receive the pulldown control signal at the first terminal 744; receive V1 at the second terminal 746; receive V2 at the third terminal 748; and provide V_{PD} at the fourth terminal 740 responsive to the pulldown control signal, V1, and V2. In some examples, V_{PD} is equal to V1 if the pulldown control signal has a first state, and V_{PD} is equal to V2 if the pulldown control signal has a second state.

In some examples, the memory cell and control logic 752 operates to: receive the address control signal at the first terminal 754; receive VBIAS at the second terminal 756; receive V_{BSA} at the third terminal 758; receive VSS at the fourth terminal 760; receive V_{PD} at the fifth terminal 762; provide VB at the sixth terminal 764 responsive to VBIAS; provide V_{ES1} at the seventh terminal 766 responsive to the address control signal, V_{BSA}, VCC2, VCC, and VSS, and provide V_{ES2} at the eighth terminal 768 responsive to the address control signal, V_{BSA}, VCC2, VCC, and VSS; and provide V_{PD} at the ninth terminal 770 responsive to the address control signal and V_{PD}. In some examples, the pulldown driver 742 and related pulldown operations are omitted. In such examples, V1, V2, and V_{PD} are also omitted.

In the example of FIG. 8E, the controller 702A is used to control the mirror position of one MEMS device or pixel. In a DMD with many MEMS devices or pixels, control operations may be distributed. In some examples, each MEMS device may have its own memory cell and control logic (e.g., the memory cell and control logic 752), while the BSA driver 732 and the pulldown driver 742 are shared by multiple MEMS devices or pixels. For example, a row of MEMS devices or pixels may share one BSA driver (e.g., the BSA driver 732) and one pulldown driver (e.g., the pulldown driver 742). As another example, a block of MEMS devices or pixels (e.g., multiple rows or multiple partial rows) may share one BSA driver (e.g., the BSA driver 732) and one pulldown driver (e.g., the pulldown driver 742).

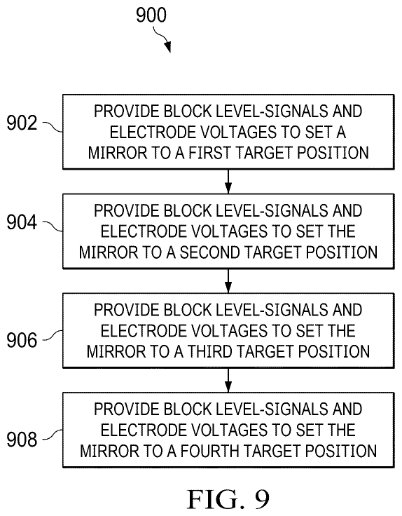

FIG. 9 is a non-contact MEMS device control method 900 in accordance with various examples. For example, non-contact MEMS device control method 900 may be performed by the controller 702 in FIG. 7A, 7B, 8A, or 8B. In the example of the FIG. 9, the non-contact MEMS device control method 900 includes providing block-level signals (e.g., VB and V_{BSA}) and electrode voltage levels (e.g., V_{ES1} and V_{ES2}) to set a mirror (e.g., the mirror 422 herein) to a first target position (e.g., the preliminary on position related to the tilt angle A as in FIGS. 7A and 7C) at block 902. At block 904, block-level signals (e.g., VB and V_{BSA}) and electrode voltage levels (e.g., V_{ES1}, V_{ES2}, and V_{PD}) are provided to set the mirror to a second target position (e.g., the target on position related to the tilt angle B as in FIGS. 7B and 7D). At block 906, block-level signals (e.g., VB and V_{BSA}) and electrode voltages (e.g., V_{ES1} and V_{ES2}) are provided to set the mirror to a third target position (e.g., the preliminary off position related to the tilt angle −A as in FIGS. 8A and 8C). At block 908, block-level signals (e.g., VB and V_{BSA}) and electrode voltages (e.g., V_{ES1}, V_{ES2}, and V_{PD}) are provided to set the mirror to a fourth target position (e.g., the target off position related to the tilt angle −B as in FIGS. 8B and 8D).

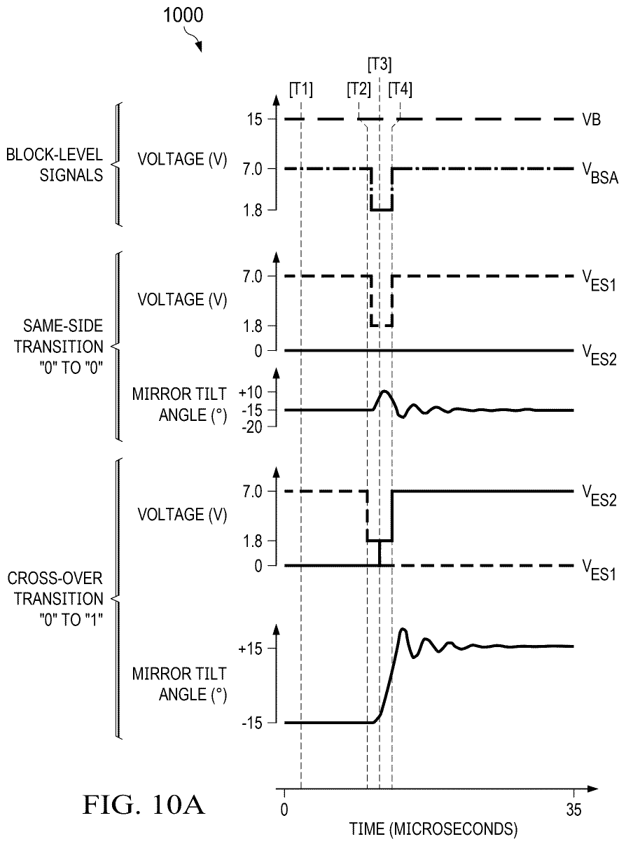

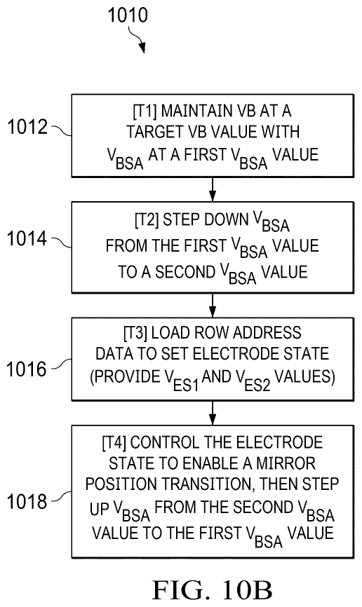

FIG. 10A is a diagram 1000 showing non-contact MEMS device waveforms in accordance with various examples. In the diagram 1000, the waveforms include block-level signals such as VB and V_{BSA}. As previously described (e.g., in FIG. 8E), VB is a bias voltage for the mirror and V_{BSA} is an internal control signal that determines which voltage states are used for V_{ES1} and V_{ES2}. The waveforms also include same-side transition waveforms and cross-over transition waveforms. The same-side transition (e.g., row address data “0” to “0”) waveforms include V_{ES1}, V_{ES2}, and mirror tilt angles. The cross-over transition (e.g., row address data “0” to “1”) waveforms include V_{ES1}, V_{ES2}, and mirror tilt angles. In some examples, the electrodes 406A and 406B in FIGS. 4A to 4D and 5, the electrodes 506A and 506B in FIG. 5B, and the electrodes 606A and 606B in FIG. 6 are ES1 electrodes. In some examples, the electrodes 408A and 408B in FIGS. 4A to 4D and 5, the electrodes 508A and 508B in FIG. 5B, and the electrodes 608A and 608B in FIG. 6 are ES2 electrodes. In the example of FIG. 10A, a first set of electrodes (e.g., electrodes 406A, 406B, and 410A) receive V_{ES1}, and a second set of electrodes (e.g., electrodes 408A, 408B, and 410B) receive V_{ES2}, and V_{PD} is not used. In the example of FIG. 10A, the mirror is initially set to −15 degrees (e.g., tilt angle −B).

For a same-side transition (e.g., the mirror tilt stays at −15 degrees): the mirror bias is maintained at a target VB value (e.g., 15V); and V_{BSA} is initially set to a first V_{BSA} value (e.g., VCC2=7V)). V_{ES2} is maintained at a ground voltage (e.g., VSS=0V). V_{ES1} is initially set to a first V_{ES1} value (e.g., VCC2=7V. At time T2, V_{BSA} is stepped down from the first V_{BSA} value to a second V_{BSA} value (e.g., VCC=1.8V); and V_{ES1} is stepped down from a first V_{ES2} value (e.g., VCC2=7V) to a second V_{ES2} value (e.g., VCC=1.8V). At time T4: V_{BSA} is stepped up from the second BSA voltage value (e.g., VCC=1.8V) to the first BSA voltage value (e.g., VCC2=7V); V_{ES1} is stepped up from the second V_{ES1} value (e.g., VCC=1.8V) to the first V_{ES1} value (e.g., VCC2=7V). For the same-side transition (e.g., row address data “0” to “0”) in diagram 1000, the mirror tilt angle starts at −15 degrees (e.g., a mirror off-state) and eventually settles to −15 degrees (e.g., a mirror off-state).

For a cross-over transition (e.g., the mirror transitions from −15 degrees to +15 degrees): the VB is maintained at a target VB value (e.g., 15V); V_{BSA} is initially set to the first BSA voltage value (e.g., VCC2=7V); V_{ES2} is initially set to a first V_{ES2} value (e.g., VSS=0V); and V_{ES1} is initially set to a first V_{ES1} value (e.g., VCC2=7V). At time T2, V_{BSA} is stepped down from the first V_{BSA} value (e.g., VCC2=7V) to a second V_{BSA} value (e.g., VCC=1.8V); and V_{ES1} is stepped down from a first V_{ES1} value (e.g., VCC2=7V) to a second V_{ES1} value (e.g., VCC=1.8V). The operations at time T2 allow the mirror to move back towards an unlanded (flat or rest) state. At time T3, row address data is loaded to a memory cell (e.g., the memory cell and control logic 752 in FIG. 8E) to adjust the electrode state. The operations at time T3 set the direction that the mirror will be attracted to. In some examples, V_{ES1} is stepped down from the second V_{ES1} value (e.g., VCC=1.8V) to a third V_{ES1} value (e.g., VSS=0V) at time T3. At time T4: V_{BSA} is stepped up from the second V_{BSA} value (e.g., VCC=1.8V) to the first V_{BSA} value (e.g., VCC2=7V); and V_{ES2} transitions from the second V_{ES2} value (e.g., VCC=1.8V) to a third V_{ES2} value (e.g., VCC2=7V). The operations at time T3 pull the mirror to a target position. For the cross-over transition (e.g., row address data “0” to “1”) in diagram 1000, the mirror tilt angle starts at −15 degrees (e.g., a mirror off-state) and eventually settles to +15 degrees (e.g., a mirror on-state).

In the example of FIG. 10A, block level signals are applied to a group of MEMS devices, regardless of individual address state. Same-side transitions and cross-over transitions for each MEMS device are performed responsive to the address state (indicated by the address control signal for each MEMS device). If a new address state matches the previous state for a MEMS device, a same-side transition is performed. If a new address state is different from the previous state for a MEMS device, a crossover transition is performed.

In some examples, the VB may be applied for a group of mirrors. To adjust individual pixels, a memory array address state may be changed to apply different voltages (e.g., VSS or VCC) to electrodes 406A and 406B, and electrodes 408A and 408B for an address state of “0”, or vice versa for address state of “1”. In some examples, the V_{BSA} may be changed between two values (e.g., VCC and VCC2) for a block of mirrors. In some examples, the V_{BSA} is adjusted up or down for a group of mirrors in a row or reset block.

FIG. 10B is a control method 1010 for a non-contact MEMS device related to the diagram 1000 in FIG. 10A. The control method 1010 uses an address control signal and no pulldown control signal. For example, the control method 1010 may be performed by the controller 702 in FIG. 7A, 7B, 8A, or 8B. In the example of the FIG. 10B, the control method 1010 includes maintaining VB at a target VB value (e.g., 15V) with V_{BSA} at a first V_{BSA} value (e.g., VCC2=7V) at block 1012. In some examples, block 1012 is performed at time T1 in the diagram 1000 of FIG. 10A. At block 1014, V_{BSA} is stepped down the first V_{BSA} value (e.g., VCC2=7V) to a second V_{BSA} value (e.g., VCC=1.8V). In some examples, block 1014 is performed at time T2 in the diagram 1000 of FIG. 10A. At block 1016, row address data is loaded to set the electrode state. In some examples, block 1016 is performed at time T3 in the diagram 1000 of FIG. 10A. In some examples, the row address data includes a “0” or “1” for each MEMS device or pixel, where “0” is an off-state and “1” is an on-state. When setting the electrode state at block 1016, V_{ES1} and/or V_{ES2} values are adjusted as needed to set the electrode state. At block 1018, the electrode state is controlled (e.g., V_{ES1} and/or V_{ES2} are stepped up or stepped down as in FIG. 10A) to enable a mirror position transition (e.g., the cross-over mirror tilt angle transitions from −15 degrees to +15 degrees), then V_{BSA} is stepped up from the second BSA voltage value (e.g., VCC=1.8V) to the first V_{BSA} value (e.g., VCC2=7V). In some examples, block 1018 is performed at time T4 in the diagram 1000 of FIG. 10A.

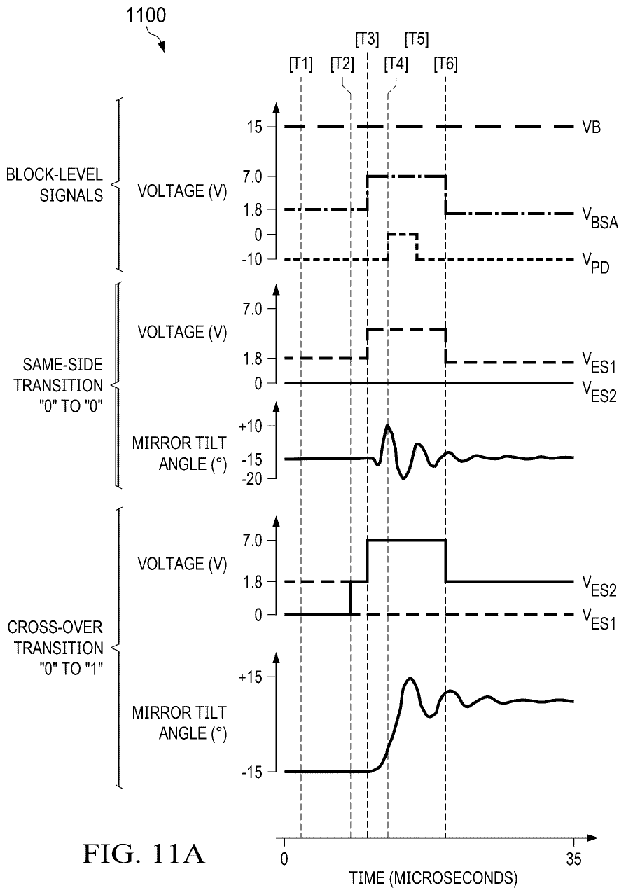

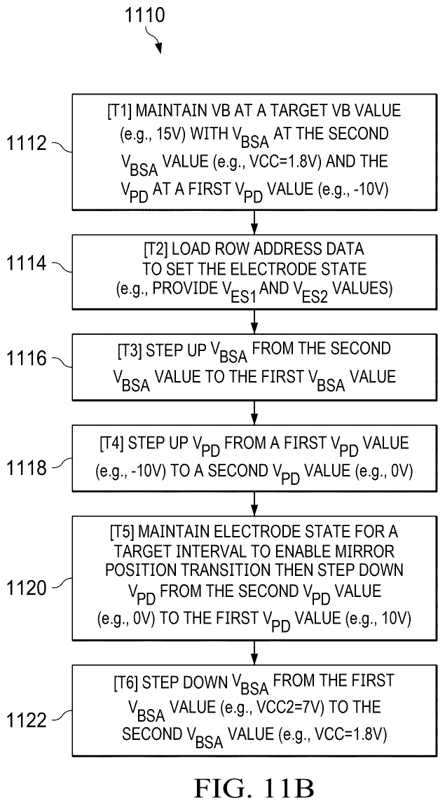

FIG. 11A is a diagram 1100 showing non-contact MEMS device waveforms in accordance with various examples. In the diagram 1100, the waveforms include block-level signals such as VB, V_{BSA}, and V_{PD}. The waveforms also include same-side transition waveforms and cross-over transition waveforms. The same-side transition waveforms include V_{ES1}, V_{ES2}, and mirror tilt angle. The cross-over transition waveforms include V_{ES1}, V_{ES2}, and mirror tilt angle. In the example of FIG. 11A, a first set of electrodes (e.g., electrodes 406A and 406B) receive V_{ES1}, a second set of electrodes (e.g., electrodes 408A and 408B) receive V_{ES2}, and a third set of electrodes (e.g., electrodes 410A and 410B) receive V_{PD}. In the example of FIG. 11A, the mirror is initially set to −15 degrees (e.g., tilt angle −B).

For a same-side transition (e.g., the mirror tilt stays at −15 degrees): VB is maintained at a target VB value (e.g., 15V); V_{BSA} is initially set to the second BSA voltage value (e.g., VCC=1.8V); and V_{PD} is initially set to a first V_{PD} value (e.g., −10V). At time T3, V_{BSA} is stepped up from the second V_{BSA} value (e.g., VCC=1.8V) to the first V_{BSA} value (e.g., VCC2=7V); and V_{ES1} is stepped up from the second V_{ES1} value (e.g., VCC=1.8V) to the first V_{ES1} value (e.g., VCC2=7V). At time T4, V_{PD} is stepped up from the first V_{PD} value (e.g., −10V) to a second V_{PD} value (e.g., 0V). At time T5, the V_{PD} is stepped down from the second V_{PD} value (e.g., 0V) to the first V_{PD} value (e.g., −10V). At time T6: V_{BSA} steps down from the first V_{BSA} value (e.g., VCC2=7V) to the second V_{BSA} value (e.g., VCC=1.8V); and V_{ES1} transitions from the first V_{ES1} value (e.g., VCC2=7V) to the second V_{ES1} value (e.g., VCC=1.8V). For the same-side transition (e.g., row address data “0” to “0”) in diagram 1100, the mirror tilt angle starts at −15 degrees (e.g., a mirror off-state) and eventually settles to −15 degrees (e.g., a mirror off-state).

For a cross-over transition (e.g., the mirror tilt transitions from −15 degrees to +15 degrees): VB is maintained at the target VB value (e.g., 15V); V_{BSA} is initially set to the second V_{BSA} value (e.g., VCC=1.8V); V_{ES1} is initially set to a first V_{ES1} value (e.g., VCC=1.8V); and V_{ES2} is initially set to the first V_{ES2} value (e.g., VSS=0V). At time T2: row address data is loaded to adjust the electrode state; V_{ES1} is stepped down from the second V_{ES1} value (e.g., VCC=1.8V) to the third V_{ES1} value (e.g., VSS=0V); and V_{ES2} is stepped up from the first V_{ES2} value (e.g., VSS=0V) to the second V_{ES2} value (e.g., VCC=1.8V). At time T3: V_{BSA} is stepped up from the second V_{BSA} value (e.g., VCC=1.8V) to the first V_{BSA} value (e.g., VCC2=7V); and V_{ES2} is stepped up from the second V_{ES2} value (e.g., VCC=1.8V) to the third V_{ES2} value (e.g., VCC2=7V). At time T4: V_{PD} is stepped up from the first V_{PD} value (e.g., −10V) to the second V_{PD} value (e.g., 0V). At time T5, V_{PD} is stepped down from the second V_{PD} value (e.g., 0V) to the first V_{PD} value (e.g., −10V). At time T6, V_{BSA} is stepped down from the first V_{BSA} value (e.g., VCC2=7V) to the second V_{BSA} value (e.g., VCC=1.8V); and V_{ES2} transitions from the third V_{ES2} value (e.g., VCC2=7V) to the second V_{ES2} value (e.g., VCC=1.8). For the cross-over transition (e.g., row address data “0” to “1”) in diagram 1100, the mirror tilt angle starts at −15 degrees (e.g., a mirror off-state) and eventually settles to +15 degrees (e.g., a mirror on-state).

FIG. 11B is a control method 1110 for a non-contact MEMS device related to the diagram 1100 in FIG. 11A. The control method 1110 uses an address control signal and a pulldown control signal. For example, the control method 1110 may be performed by the controller 702 in FIG. 7A, 7B, 8A, or 8B. In the example of the FIG. 11B, the control method 1110 includes maintaining VB at a target VB value (e.g., 15V) with V_{BSA} at the second V_{BSA} value (e.g., VCC=1.8V) and with V_{PD} at a first V_{PD} value (e.g., −10V) at block 1112. In some examples, block 1112 is performed at time T1 in the diagram 1100 of FIG. 11A. At block 1114, row address data is loaded to set the electrode state. In some examples, block 1114 is performed at time T2 in the diagram 1100 of FIG. 11A. In some examples, the row address data includes a “0” or “1” for each MEMS device or pixel, where “0” is an off-state and “1” is an on-state. When setting the electrode state at block 1114, V_{ES1} and/or V_{ES2} values are provided and/or adjusted as needed to set the electrode state. At block 1116, V_{BSA} is stepped up the second V_{BSA} value (e.g., VCC=1.8V) to the first V_{BSA} value (e.g., VCC2=7V). In some examples, block 1116 is performed at time T3 in the diagram 1100 of FIG. 11A. In some examples, V_{ES1} and/or V_{ES2} values may be adjusted at time T3. At block 1118, V_{PD} is stepped up from the first V_{PD} value (e.g., −10V) to the second V_{PD} value (e.g., 0V). In some examples, block 1118 is performed at time T4 in the diagram 1100 of FIG. 11A. At block 1120, the electrode state (e.g., V_{ES1}, V_{ES2}, and V_{PD}) are maintained for a target interval (e.g., a pulse time), then V_{PD} is stepped down from the second V_{PD} value (e.g., 0V) to the first V_{PD} value (e.g., −10V). In some examples, block 1120 is performed at time T5 in the diagram 1100 of FIG. 11A. At block 1122, V_{BSA} is stepped down from the first V_{BSA} value (e.g., VCC2=7V) to the second V_{BSA} value (e.g., VCC=1.8V). In some examples, block 1122 is performed at time T6 in the diagram 1100 of FIG. 11A.

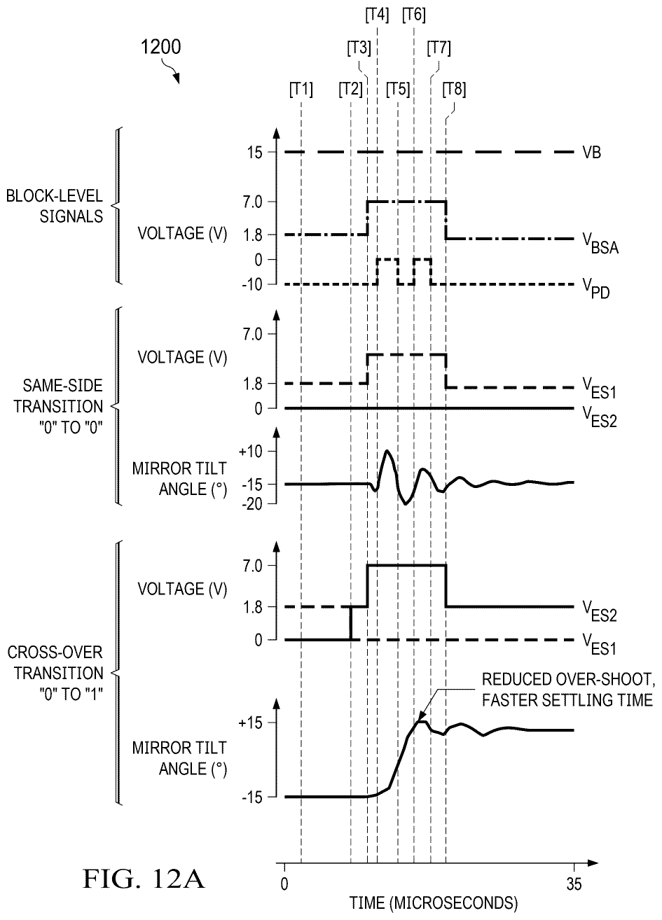

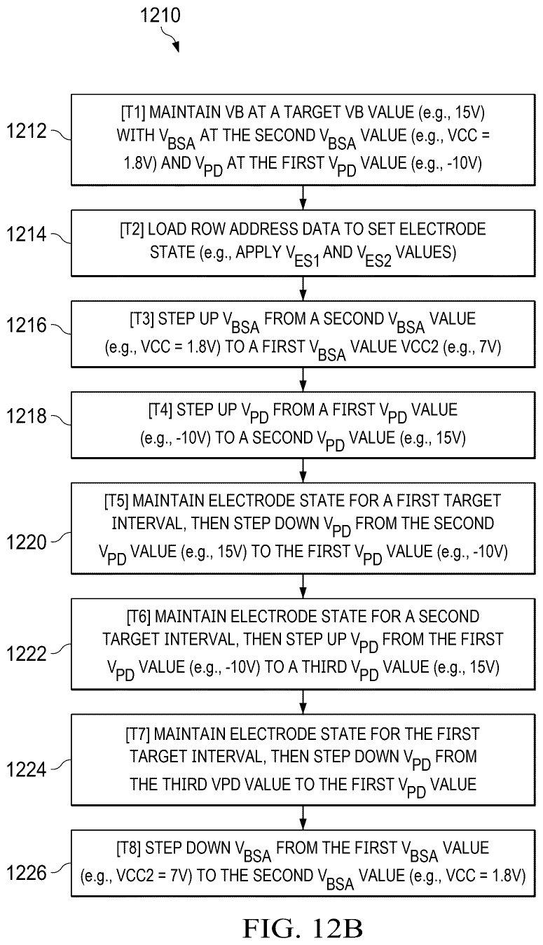

FIG. 12A is a diagram 1200 showing non-contact MEMS device waveforms in accordance with various examples. In the diagram 1200, the waveforms include block-level signals such as VB, V_{BSA}, and V_{PD}. The waveforms also include same-side transition waveforms and cross-over transition waveforms. The same-side transition waveforms include V_{ES1}, V_{ES2}, and mirror tilt angle. The cross-over transition waveforms include V_{ES1}, V_{ES2}, and mirror tilt angle. In the example of FIG. 12A, a first set of electrodes (e.g., electrodes 406A and 406B) receive V_{ES1}, a second set of electrodes (e.g., electrodes 408A and 408B) receive V_{ES2}, and a third set of electrodes (e.g., electrodes 410A and 410B) receive V_{PD}. In the example of FIG. 12A, the mirror is initially set to −15 degrees (e.g., tilt angle −B).

For a same-side transition (e.g., the mirror tilt stays at −15 degrees): VB is maintained at a target VB value (e.g., 15V); V_{BSA} is initially set to the second BSA voltage value (e.g., VCC=1.8V); and V_{PD} is initially set to a first V_{PD} value (e.g., −10V). At time T3, V_{BSA} is stepped up from the second V_{BSA} value (e.g., VCC=1.8V) to the first V_{BSA} value (e.g., VCC2=7V); and V_{ES1} is stepped up from the second V_{ES1} value (e.g., VCC=1.8V) to the first V_{ES1} value (e.g., VCC2=7V). At time T4, V_{PD} is stepped up from the first V_{PD} value (e.g., −10V) to a second V_{PD} value (e.g., 0V). At time T5, V_{PD} is stepped down from the second V_{PD} value (e.g., 0V) to the first V_{PO} value (e.g., −10V). At time T6, V_{PO} is stepped up from the first V_{PO} value (e.g., −10V) to a second V_{PO} value (e.g., 0V). At time T7, V_{PO} is stepped down from the second V_{PO} value (e.g., 0V) to the first V_{PO} value (e.g., −10V). At time T8, V_{ES1} transitions from the first V_{ES1} value (e.g., VCC2=7V) to the second V_{ES1} value (e.g., VCC=1.8V). For the same-side transition (e.g., row address data “0” to “0”) in diagram 1200, the mirror tilt angle starts at −15 degrees (e.g., a mirror off-state) and eventually settles to −15 degrees (e.g., a mirror off-state).

For a cross-over transition (e.g., the mirror tilt transitions from −15 degrees to +15 degrees): VB is maintained at the target VB value (e.g., 15V); V_{BSA} is initially set to the second V_{BSA} value (e.g., VCC=1.8V); V_{ES1} is initially set to a first V_{ES1} value (e.g., VCC=1.8V); and V_{ES2} is initially set to the first V_{ES2} value (e.g., VSS=0V). At time T2: row address data is loaded to adjust the electrode state; V_{ES1} is stepped down from the second V_{ES1} value (e.g., VCC=1.8V) to the third V_{ES1} value (e.g., VSS=0V); and V_{ES2} is stepped up from the first V_{ES2} value (e.g., VSS=0V) to the second V_{ES2} value (e.g., VCC=1.8V). At time T3: V_{BSA} is stepped up from the second V_{BSA} value (e.g., VCC=1.8V) to the first V_{BSA} value (e.g., VCC2=7V); and V_{ES2} is stepped up from the second V_{ES2} value (e.g., VCC=1.8V) to the third V_{ES2} value (e.g., VCC2=7V). At time T4: V_{PD} is stepped up from the first V_{PD} value (e.g., −10V) to the second V_{PD} value (e.g., 0V). At time T5, V_{PD} is stepped down from the second V_{PD} value (e.g., 0V) to the first V_{PD} value (e.g., −10V). At time T6: V_{PD} is stepped up from the first V_{PD} value (e.g., −10V) to the second V_{PO} value (e.g., 0V). At time T7, V_{PO} is stepped down from the second V_{PO} value (e.g., 0V) to the first V_{PO} value (e.g., −10V). At time T8, V_{BSA} is stepped down from the first V_{BSA} value (e.g., VCC2=7V) to the second V_{BSA} value (e.g., VCC=1.8V); and V_{ES2} transitions from the third V_{ES2} value (e.g., VCC2=7V) to the second V_{ES2} value (e.g., VCC=1.8). In the example of FIG. 12A, multiple iterations of V_{PO} are used to decrease overshoot and settling time. For the cross-over transition (e.g., row address data “0” to “1”) in diagram 1200, the mirror tilt angle starts at −15 degrees (e.g., a mirror off-state) and eventually settles to +15 degrees (e.g., a mirror on-state).

FIG. 12B is a control method 1210 for a non-contact MEMS device related to the diagram 1200 in FIG. 12A. The control method 1210 uses an address control signal a pulldown control signal, and a retarding pulse to reduce mirror position overshoot and settling time. For example, the control method 1210 may be performed by the controller 702 in FIG. 7A, 7B, 8A, or 8B. In the example of the FIG. 12B, the control method 1210 includes maintaining VB at a target VB value (e.g., 15V) with V_{BSA} at the second V_{BSA} value (e.g., VCC=1.8V) and with V_{PD} at a first V_{PD} value (e.g., −10V) at block 1212. In some examples, block 1212 is performed at time T1 in the diagram 1200 of FIG. 12A. At block 1214, row address data is loaded to set the electrode state. In some examples, block 1214 is performed at time T2 in the diagram 1200 of FIG. 12A. In some examples, the row address data includes a “0” or “1” for each MEMS device or pixel, where “0” is an off-state and “1” is an on-state. When setting the electrode state at block 1214, V_{ES1} and/or V_{ES2} values are provided and/or adjusted as needed to set the electrode state. At block 1216, V_{BSA} is stepped up the second V_{BSA} value (e.g., VCC=1.8V) to the first V_{BSA} value (e.g., VCC2=7V). In some examples, block 1216 is performed at time T3 in the diagram 1200 of FIG. 12A. In some examples, V_{ES1} and/or V_{ES2} values may be adjusted at time T3. At block 1218, V_{PD} is stepped up from the first V_{PD} value (e.g., −10V) to the second V_{PD} value (e.g., 0V). In some examples, block 1218 is performed at time T4 in the diagram 1200 of FIG. 12A. At block 1220, the electrode state (e.g., V_{ES1}, V_{ES2}, and V_{PD}) is maintained for a first target interval (e.g., a pulse time), then V_{PD} is stepped down from the second V_{PD} value (e.g., 0V) to the first V_{PD} value (e.g., −10V). In some examples, block 1220 is performed at time T5 in the diagram 1200 of FIG. 12A. At block 1222, the electrode state (e.g., V_{ES1}, V_{ES2}, and V_{PD}) is maintained for a second target interval (e.g., a wait interval), then V_{PD} is stepped up from the first V_{PD} value (e.g., −10V) to a third V_{PD} value (e.g., +15V). In some examples, block 1222 is performed at time T6 in the diagram 1200 of FIG. 12A. At block 1224, the electrode state (e.g., V_{ES1}, V_{ES2}, and V_{PD}) is maintained for the first target interval (e.g., a pulse time), then V_{PD} is stepped down from the third V_{PD} value (e.g., 15V) to the first V_{PD} value (e.g., −10V). In some examples, block 1224 is performed at time T7 in the diagram 1200 of FIG. 12A. At block 1226, V_{BSA} is stepped down from the first V_{BSA} value (e.g., VCC2=7V) to the second V_{BSA} value (e.g., VCC=1.8V). In some examples, block 1226 is performed at time T8 in the diagram 1200 of FIG. 12A.

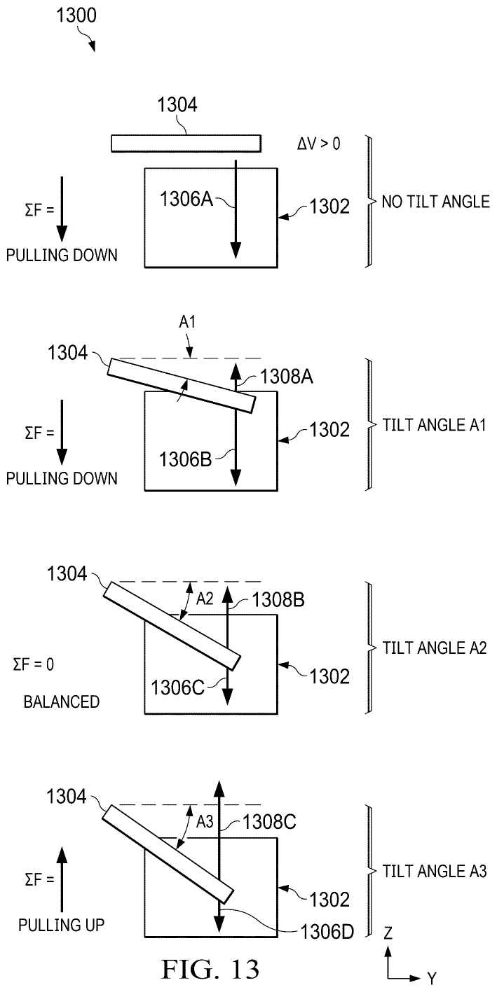

FIG. 13 is a diagram 1300 showing different hinge extension positions in accordance with various examples. In the diagram 1300, an electrode 1302 and hinge extension 1304 are represented. The electrode 1302 is an example of any of the electrodes 406A, 406B, 408A, 408B, 410A, and 410B in FIGS. 4A to 4B, and 5A, any of the electrodes 506A, 506B, 508A, 508B, 510A, and 510B in FIG. 5B, or any of the electrodes 606A, 606B, 608A, 608B, 610A, and 610B in FIG. 6. The hinge extension 1304 is an example of any of the extensions 418A to 418D in FIGS. 4A to 4D, 5A, 7A to 7D, 8A to 8D, or any of the extensions 518A to 518D in FIG. 5B. In the diagram 1300, the hinge extension 1304 may be in different tilt angles such as no tilt angle, tilt angle A1, tilt angle A2, or tilt angle A3 as represented in the diagram 1300. With no tilt angle: the hinge extension 1304 is parallel to the Y direction; there is a downward force 1306A due to the relative voltages of the hinge extension 1304 and the electrode 1302 and related electrostatic forces; and the net forces on the hinge extension 1304 pull the hinge extension 1304 downward. With tilt angle A1, the hinge extension 1304 has the angle A1 relative to the Y direction. With the tilt angle A1: there is a downward force 1306B and an upward force 1308A due to the relative voltages of the hinge extension 1304 and the electrode 1302 and related electrostatic forces; and the net forces on the hinge extension 1304 pull the hinge extension 1304 downward.

In the example of FIG. 13, application of control voltages to respective electrodes produces an electrostatic moment acting on the extensions (e.g., extensions 418A to 418D, extensions 518A to 518D, or extensions 548A to 548D herein) of a hinge (e.g., the hinge 411, 511, or 541 herein), which is attached to a related mirror. Without application of control voltages, torsion forces of the hinge produce a separate restoring moment that pulls the mirror back toward the flat or rest position. When electrostatically actuated to a stable tilted position, the moment produced by the torsion hinge is balanced by the electrostatic moment produced by application of control voltages to respective electrodes.

With tilt angle A2, the hinge extension 1304 has the angle A2 relative to the Y direction. With the tilt angle A2: there is a downward force 1306C and an upward force 1308B due to the relative voltages of the hinge extension 1304 and the electrode 1302 and related electrostatic forces; and the net forces on the hinge extension 1304 are balanced. With tilt angle A2, the hinge extension 1304 can be maintained in a non-contact balanced state. With tilt angle A3, the hinge extension 1304 has the angle A3 relative to the Y direction. With the tilt angle A3: there is a downward force 1306D and an upward force 1308C due to the relative voltages of the hinge extension 1304 and the electrode 1302 and related electrostatic forces; and the net forces on the hinge extension 1304 pull the hinge extension 1304 upward.

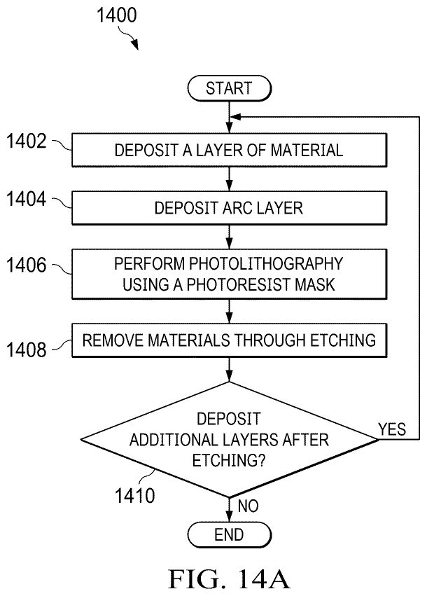

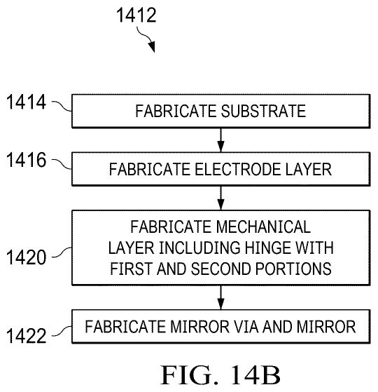

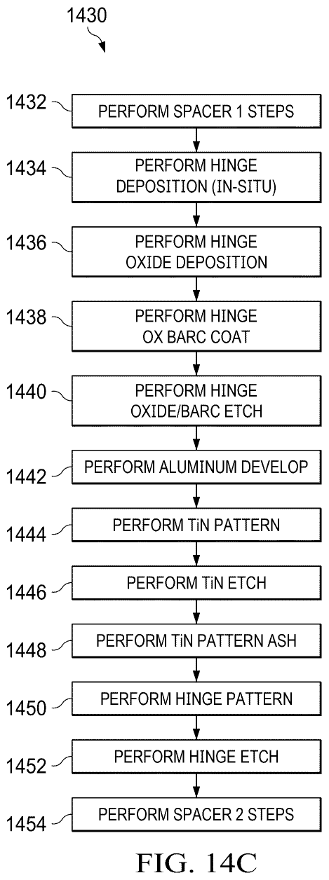

FIGS. 14A to 14C are fabrication methods 1400, 1412, and 1430 for a non-contact MEMS device in accordance with various examples. The fabrication method 1400 of FIG. 14A includes depositing a layer of material at block 1402. At block 1404, an anti-reflective coating (ARC) is deposited. At block 1406, photolithography is performed using a photoresist mask. At block 1408, materials are removed through etching. If additional layers are to be deposited after etching (block 1410), the fabrication method 1400 returns to block 1402. Otherwise, if no additional layers are to be deposited after etching (block 1410), the fabrication method 1400 ends.

As an example, during a first iteration of the fabrication method 1400, an electrode layer with a target thickness (e.g., in the Z direction herein) is formed at block 1402 and an ARC layer is deposited over the electrode layer at block 1404. The photolithography at block 1406 forms a pattern in the ARC layer exposing the electrode layer. Etching at block 1408 removes electrode layer material, resulting in hinge electrode pads (e.g., hinge via hinge electrode pads 404A and 404B in FIGS. 4A to 4D, or hinge electrode pads 604 in FIG. 6) and electrodes (e.g., electrodes 406A and 406B, 408A and 408B, 410A and 410B in FIGS. 4A to 4D, and 5A, electrodes 506A and 506B, 508A and 508B, 510A and 510B in FIG. 5B, or electrodes 606A and 606B, 608A and 608B, and 610A and 610B in FIG. 6).

During a second iteration of the fabrication method 1400, a hinge layer (e.g., for the hinge 411 in FIGS. 4A to 4D, 5A, and 5B, or for the hinge 541 in FIG. 5C) with a first portion (e.g., the first portion 414 in FIGS. 4A to 4D, 5A, and 5B, or the first portion 544 in FIG. 5C) and a second portion (e.g., the second portion 416 in FIGS. 4A to 4D, and 5A, the second portion 516 in FIG. 5B, or the second portion 546 in FIG. 5C) is formed at block 1402 and an ARC layer is deposited over the hinge layer at block 1404. In some examples, the first portion of the hinge formed at block 1402 has a first target thickness (e.g., in the Z direction herein) and the second portion of the hinge formed at block 1402 has a second target thickness that is greater than the first target thickness. The photolithography at block 1406 forms a pattern in the ARC layer exposing the hinge layer. Etching at block 1408 removes hinge layer material, resulting in a first portion of a hinge with the first target thickness (e.g., the first portion 414 of the hinge 411 in FIGS. 4A to 4D, and 5A, or the first portion 414 of the hinge 511 in FIG. 5B).

During other iterations of the fabrication method 1400, hinge vias (e.g., hinge vias 412A and 412B in FIGS. 4A to 4D, 5A, 5B), a mirror via (e.g., the mirror via 420 in FIGS. 4A to 4D), and a mirror (e.g., the mirror 422 in FIGS. 4A to 4D, 5A, and 5B) are fabricated.

In the fabrication method 1412 of FIG. 14B, a substrate or base is fabricated at block 1414. In some examples, block 1414 involves a multiple-step photolithographic and physio-chemical process. Example steps include: thermal oxidation; thin-film deposition; ion-implantation; and etching to gradually form electronic circuits on a wafer. In some examples, the substrate or base fabricated at block 1414 includes circuitry or memory cells for MEMS device control operations. At block 1416, an electrode layer (e.g., the electrode layer 401 in FIG. 4A) is fabricated (e.g., using or more iterations of the fabrication method 1400 in FIG. 14A). The electrode layer fabricated at block 1416 may include hinge vias (e.g., hinge electrode pads 404A and 404B in FIGS. 4A to 4D), and electrodes (e.g., electrodes 406A, 406B, 408A, 408B, 410A, and 410B in FIGS. 4A to 4D). At block 1420, a mechanical layer is fabricated (e.g., using one or more iterations of the fabrication method 1400 in FIG. 14A). In some examples, the mechanical layer fabricated at block 1420 includes a hinge with extensions (e.g., hinge 411 in FIGS. 4A to 4D) and hinge vias (e.g., hinge vias 412A and 412B in FIGS. 4A to 4D). At block 1422, a mirror via (e.g., the mirror via 420 in FIGS. 4A to 4D) and mirror (e.g., the mirror 422 in FIGS. 4A to 4D) is fabricated (e.g., using or more iterations of the fabrication method 1400 in FIG. 14A).

In the fabrication method 1430 of FIG. 14C, a hinge with extensions (e.g., the hinge 411 in FIGS. 4A and 4D) is fabricated. As shown, the fabrication method 1430 includes: performing spacer (sacrificial layer) 1 steps at block 1432; performing hinge deposition at block 1434; performing hinge oxide deposition at block 1436; performing hinge oxide BARC (bottom-layer anti-reflective coating) at block 1438; performing hinge oxide/BARC etch at block 1440; performing aluminum develop at block 1442; performing titanium nitride (TiN) pattern at block 1444; performing TiN etch at block 1446; performing TiN pattern ash at block 1448; performing hinge pattern at block 1450; performing hinge etch at block 1452; and performing spacer (sacrificial layer) 2 steps at block 1454. In some examples, the fabrication method 1430 is performed at block 1420 of the fabrication method 1412 in FIG. 14B.

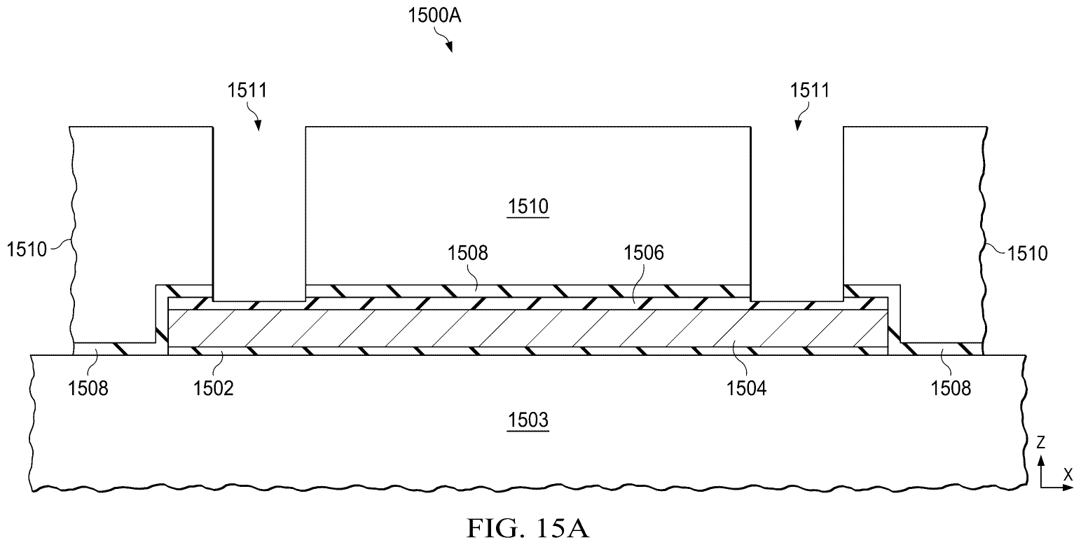

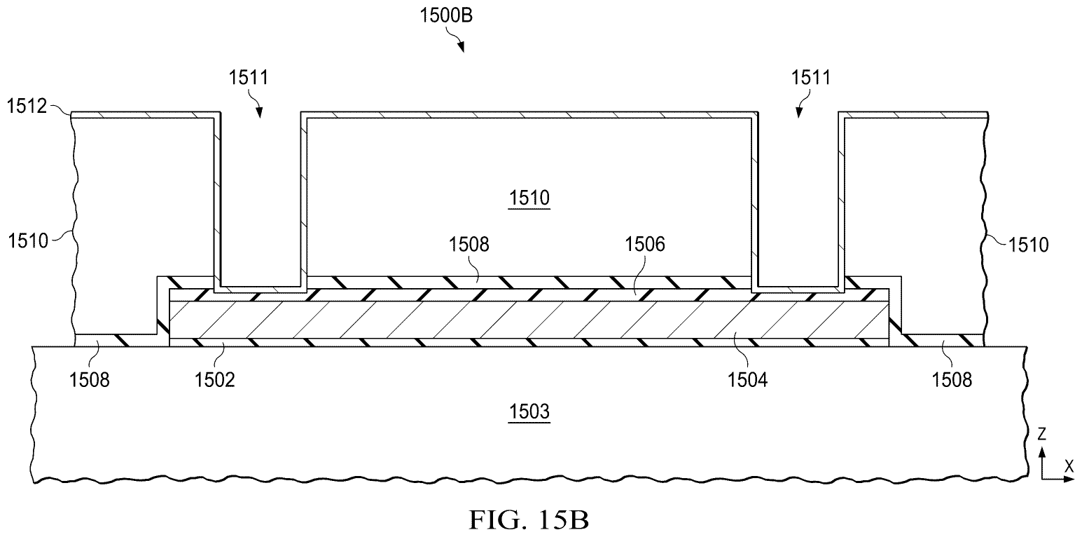

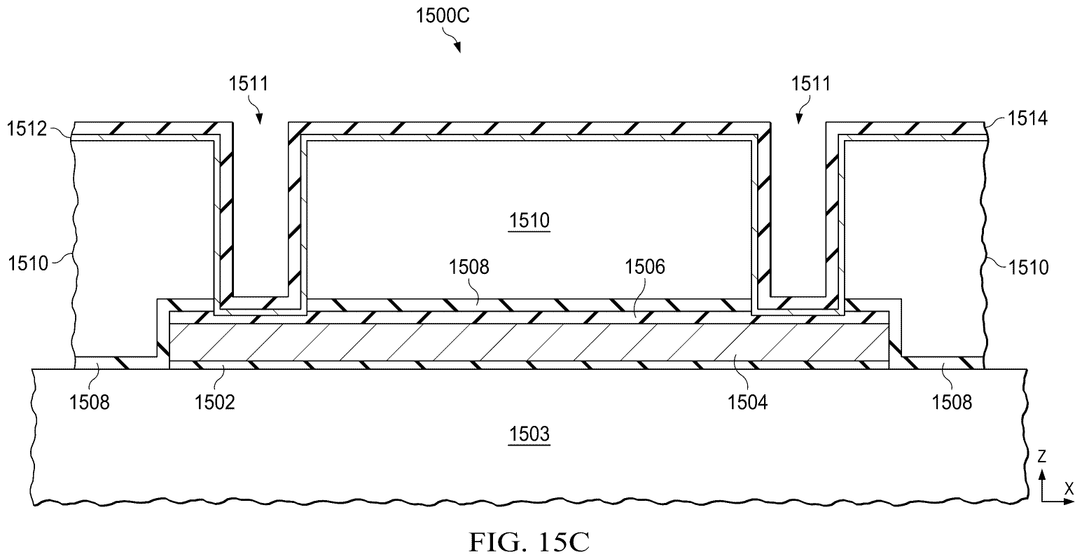

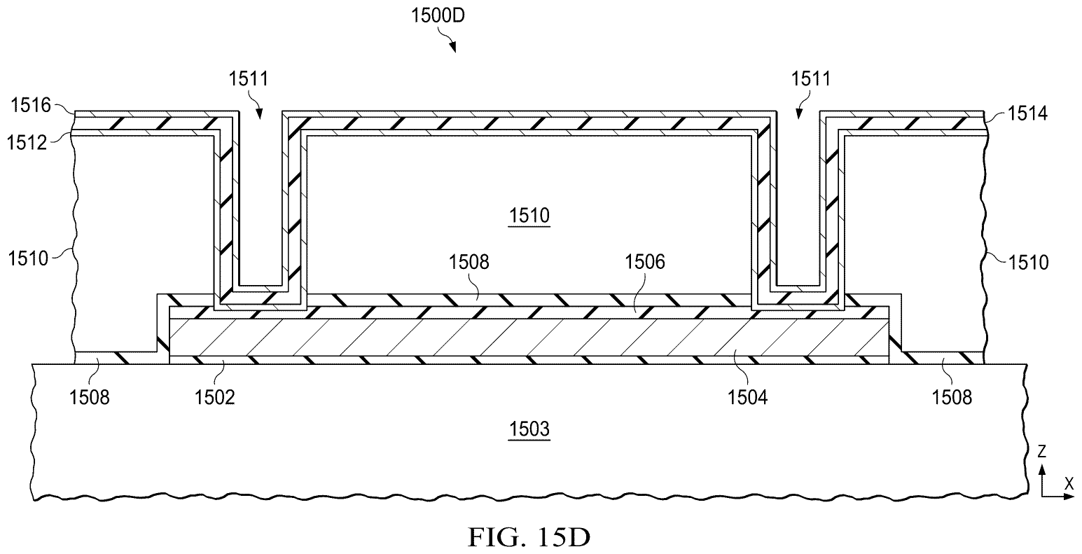

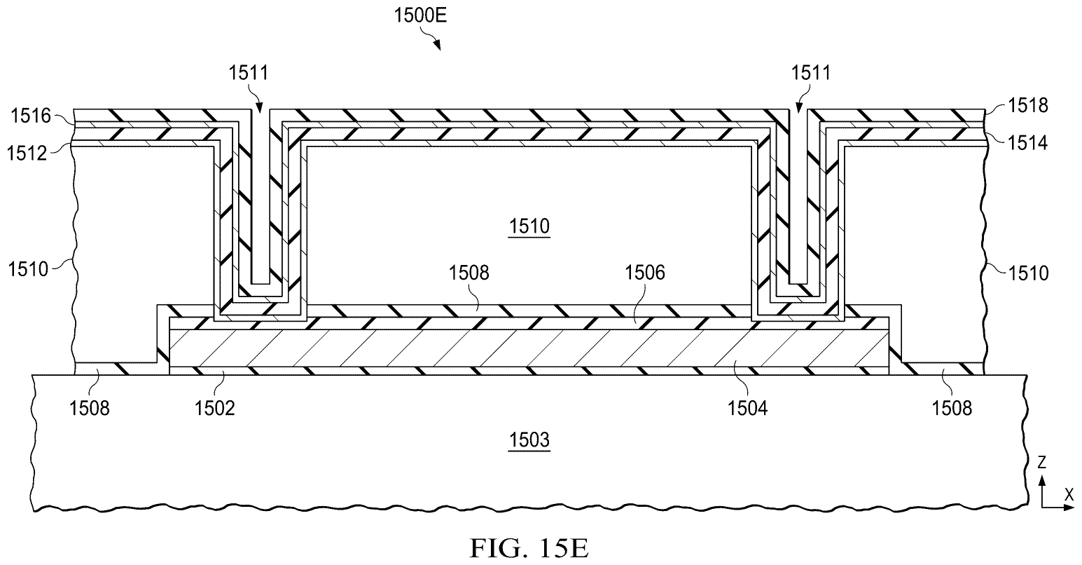

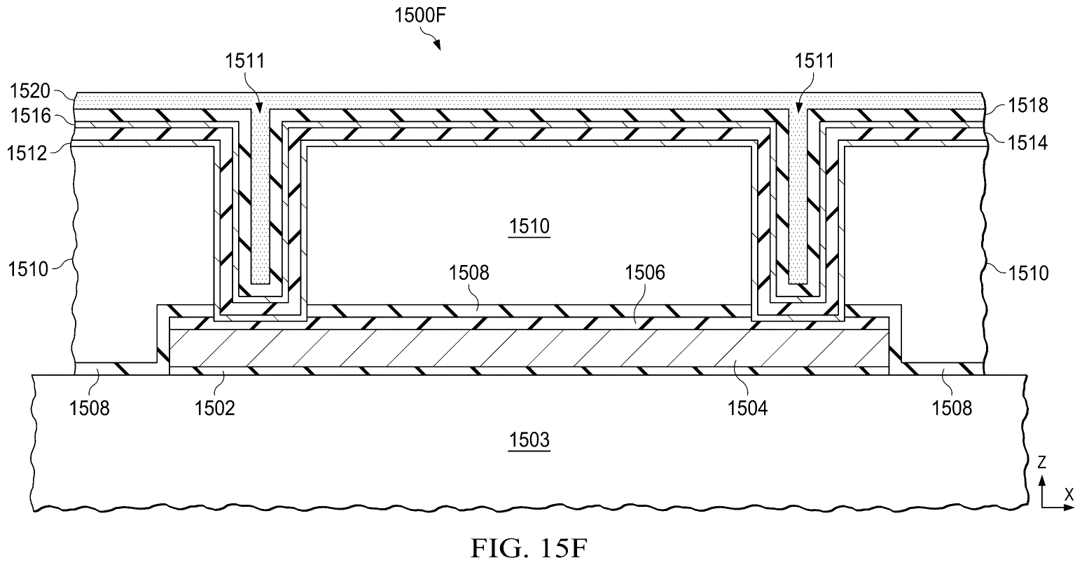

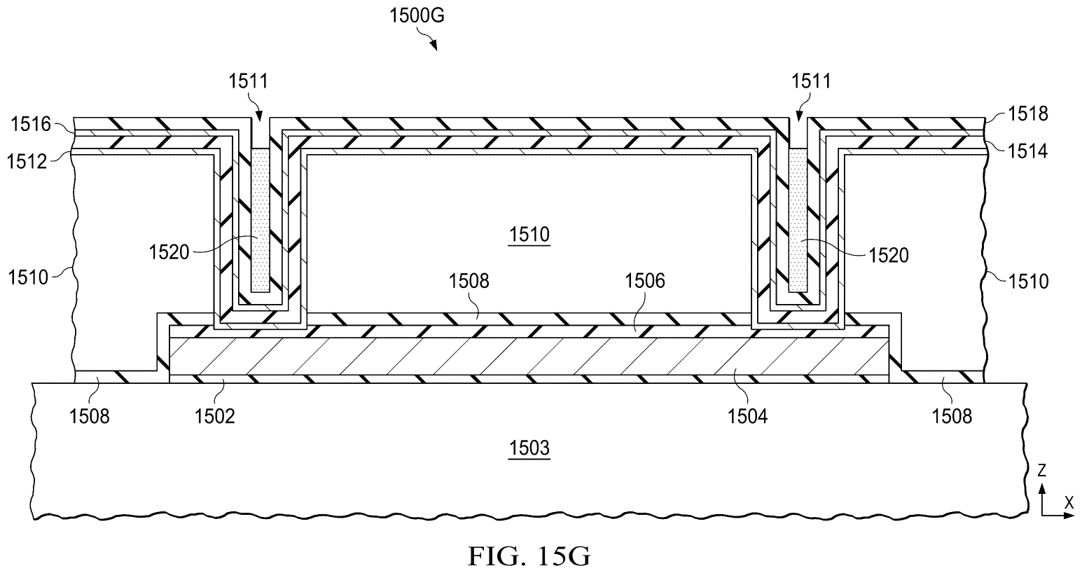

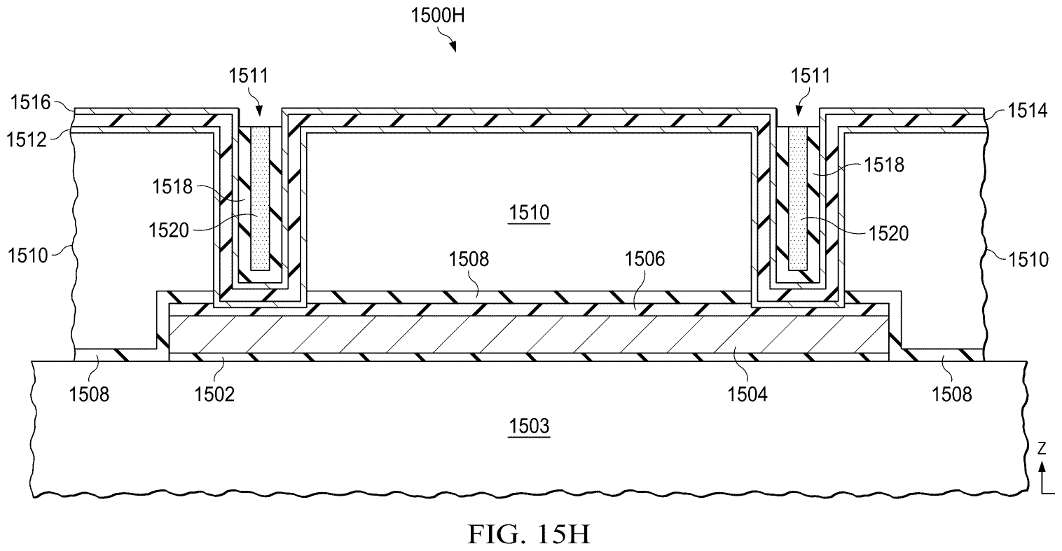

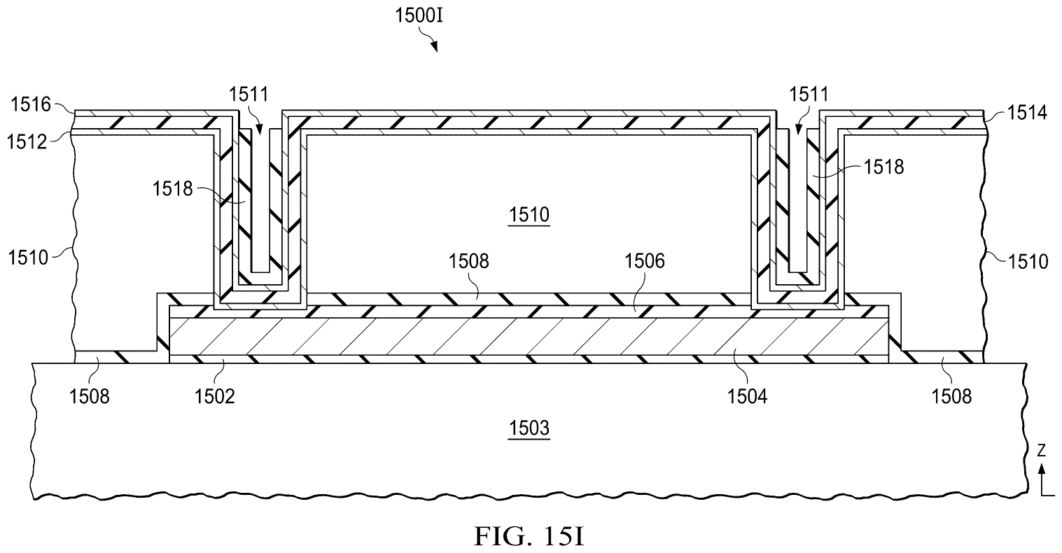

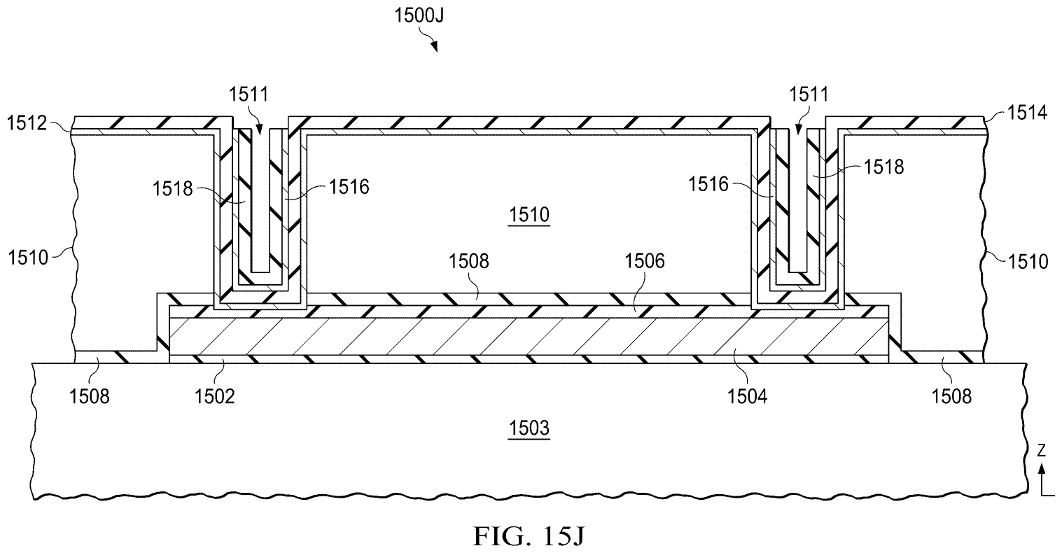

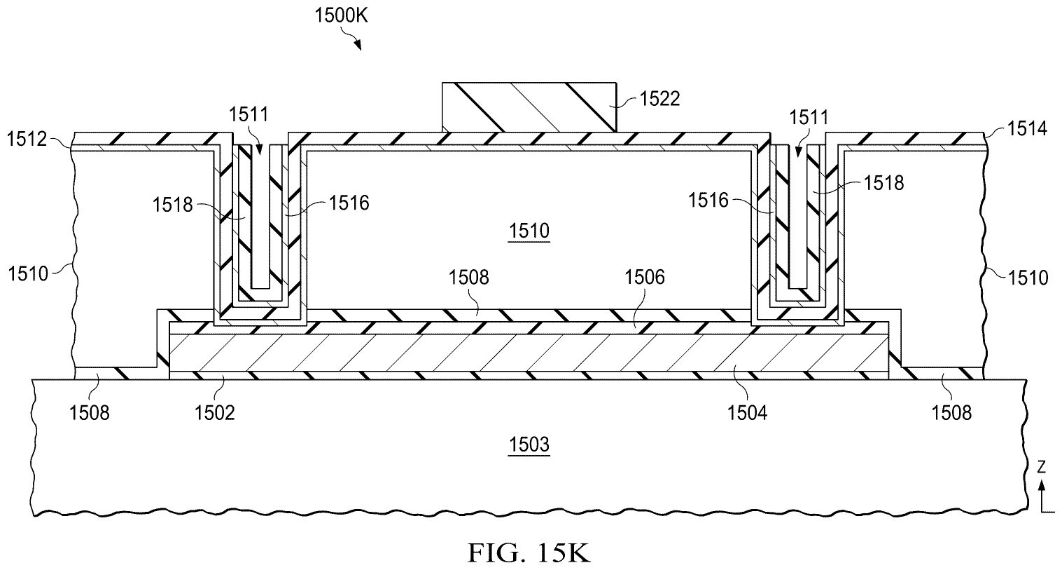

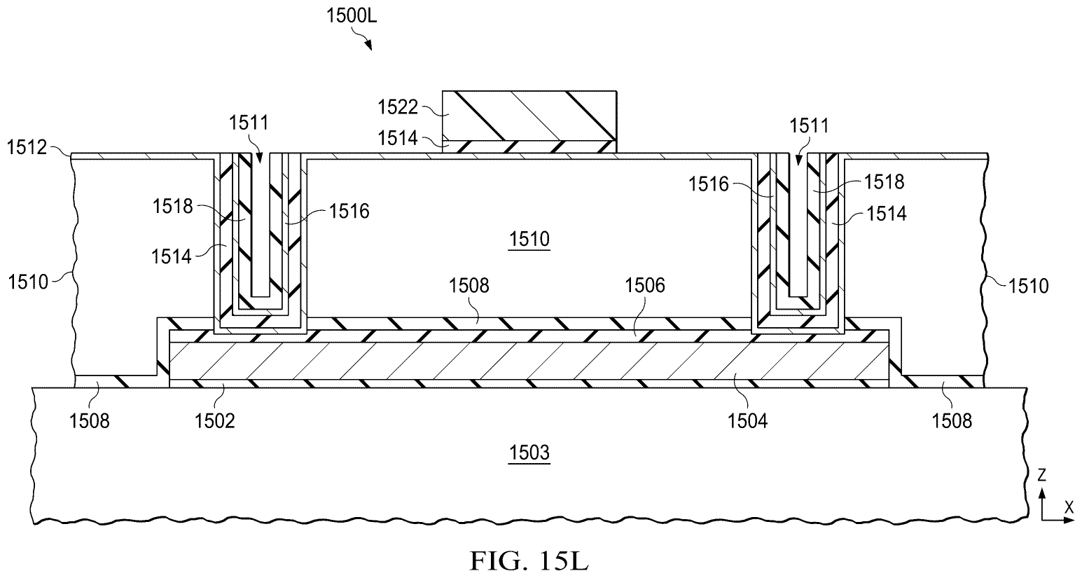

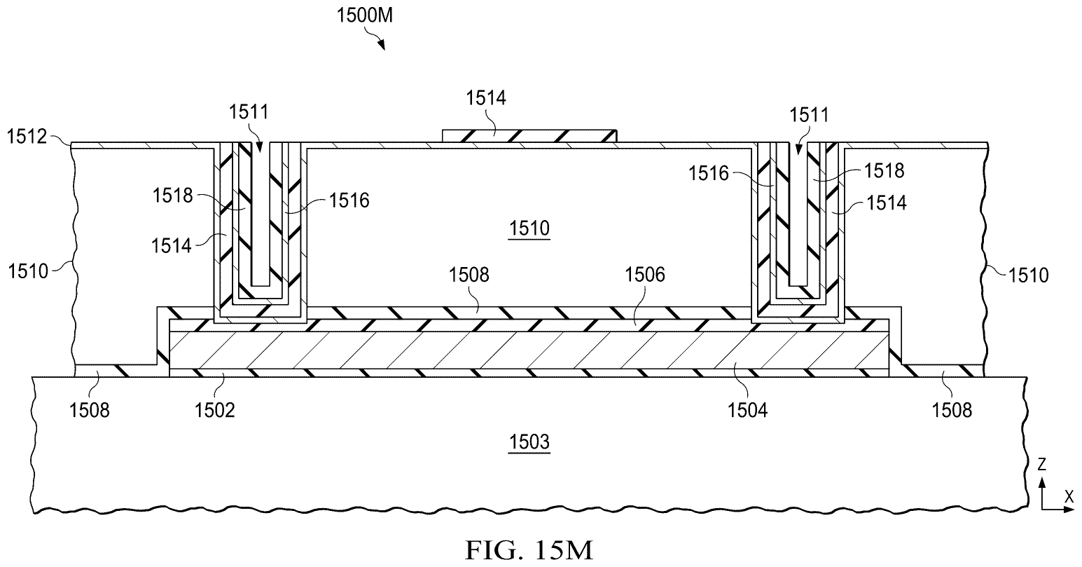

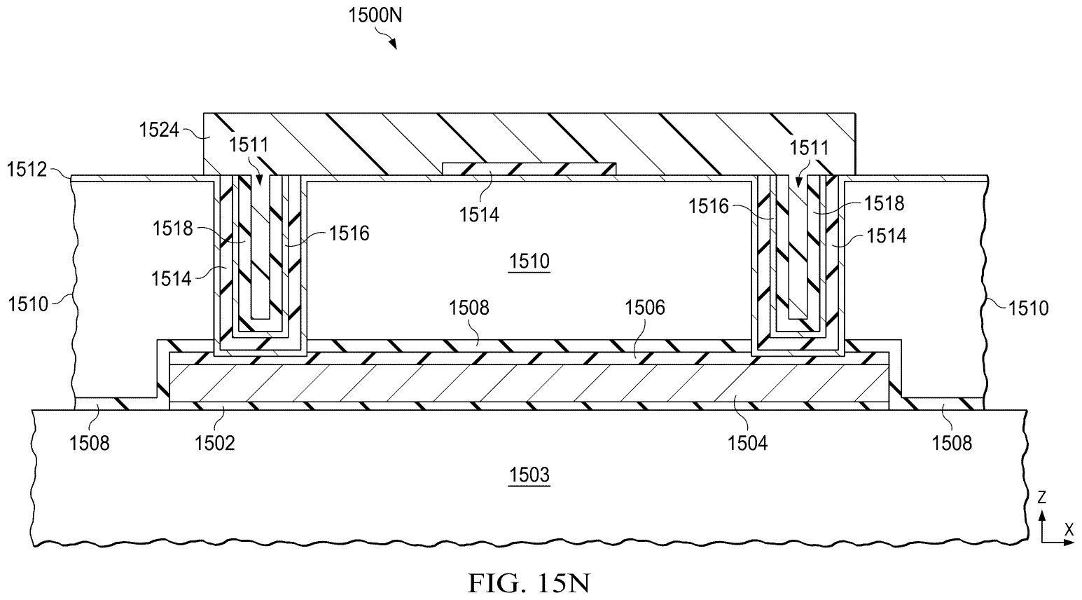

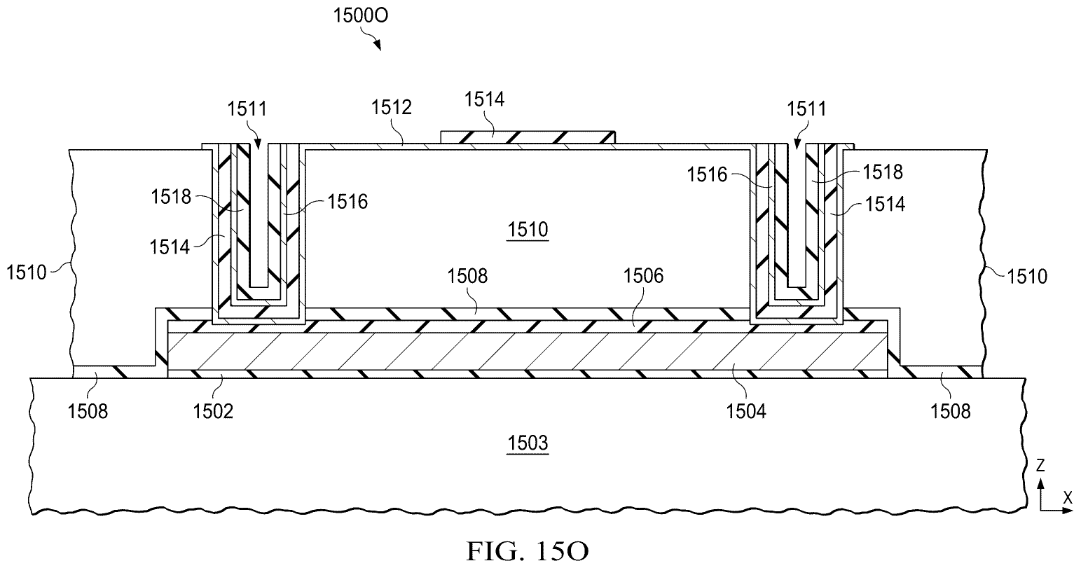

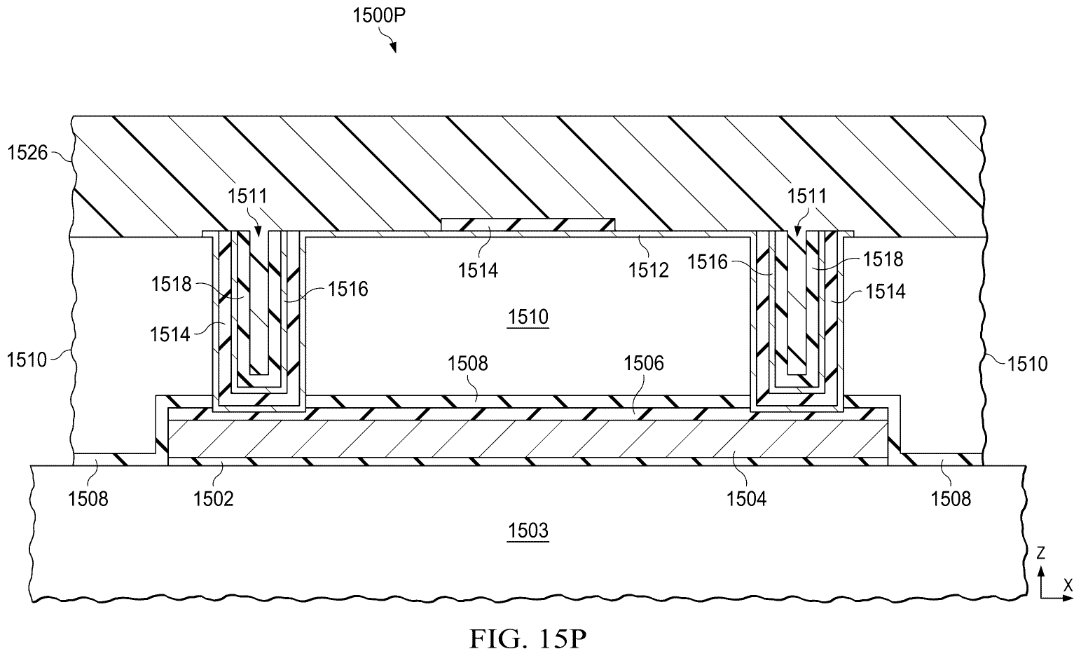

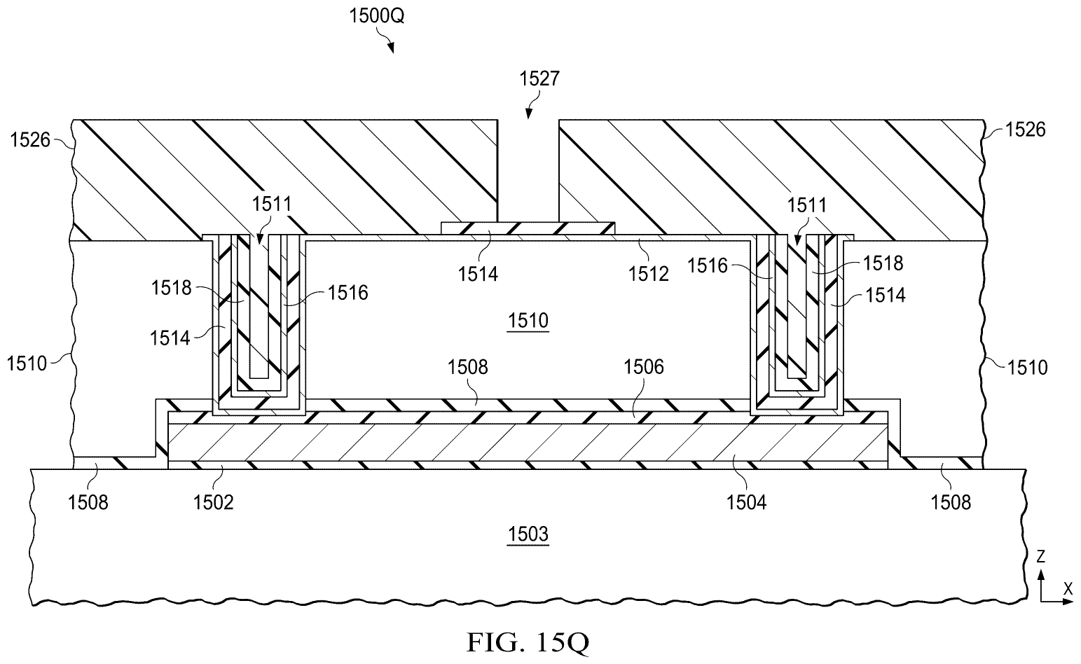

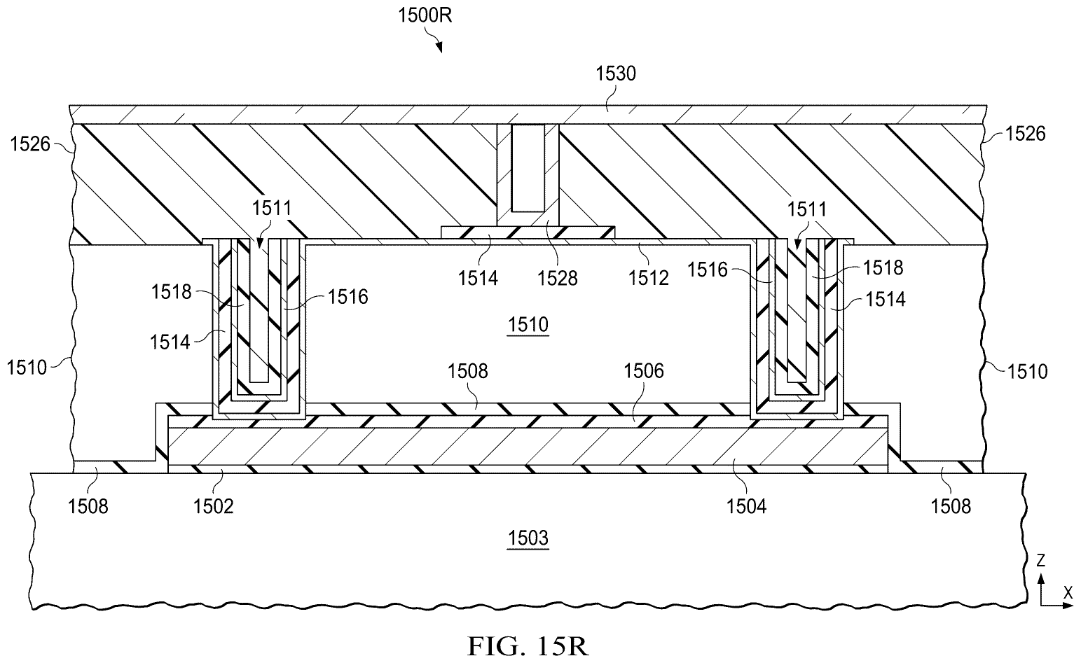

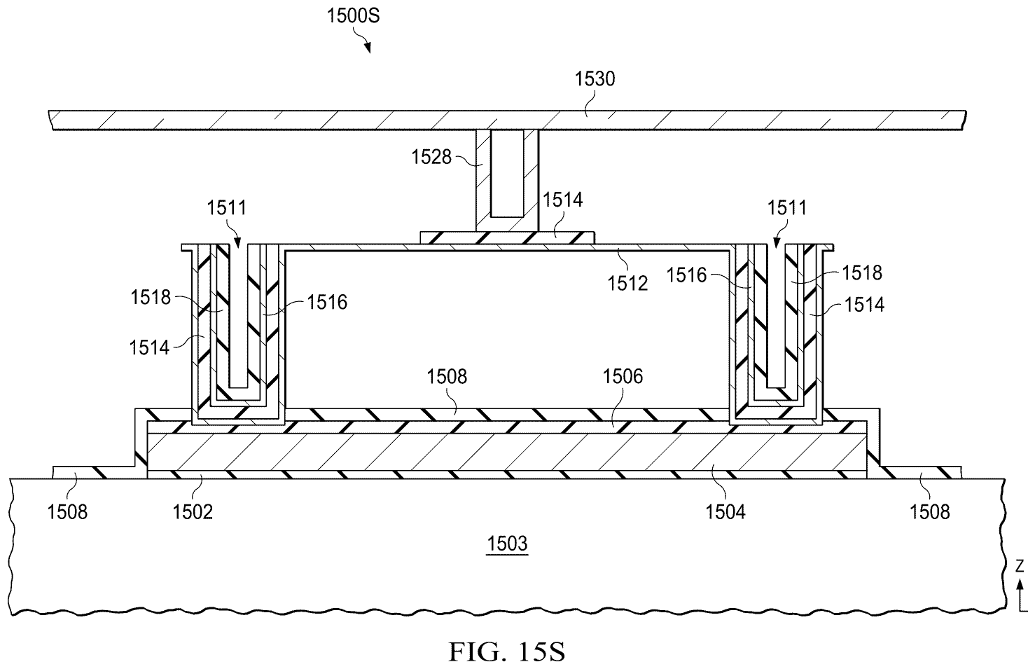

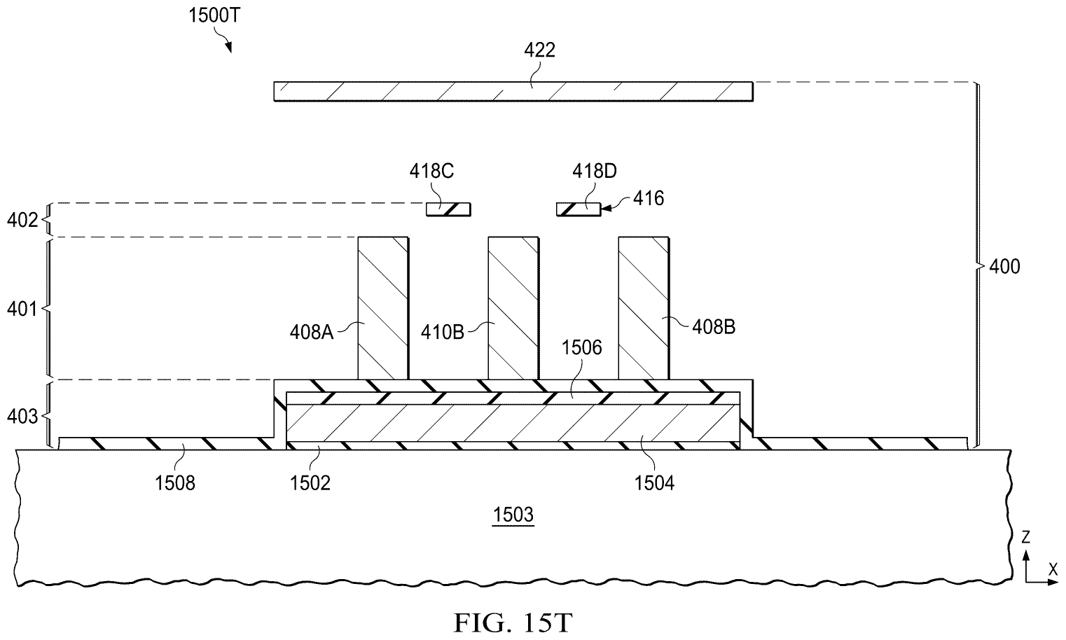

Some of the fabrication method 1430 is represented using FIGS. 15A to 15O, which are cross-sectional views of a non-contact MEMS device (e.g., the non-contact MEMS device 400 in FIGS. 4A to 4D). The cross-sectional view 1500A of FIG. 15A shows results including the spacer 1 steps of block 1432. In the cross-sectional view 1500A, a spacer (sacrificial) layer 1510 is over substrate 1503, metal layers 1502, 1504, and 1506, and ARC layer 1508. The metal layers 1502, 1504, and 1506, and ARC layer 1508 were fabricated previously, for example, at block 1414 of the fabrication method 1412. In some examples, the spacer layer 1510 is spin-on carbon (SOC), the metal layers 1502 include a titanium (Ti) layer and a titanium nitride (e.g., TiN_B) layer, the metal layer 1504 includes an aluminum titanium silicon (AITiSi) layer, and the metal layers 1506 include a titanium nitride (e.g., TiN_T) layer and a titanium oxide (TiOx) layer. In the example of FIG. 15A, etching (e.g., block 1408 of the fabrication method 1400 in FIG. 14A) has been performed to form via gaps 1511 in the spacer layer 1510, where the via gaps 1511 extend to the metal layers 1506 (e.g., through the TiOx layer and to the TiN_T layer).

The cross-sectional views 1500B to 1500D of FIGS. 15B to 15D show results of hinge deposition operations (e.g., block 1434 of the fabrication method 1430 in FIG. 14C) over the spacer layer 1510 and in the via gaps 1511. In the cross-sectional view 1500B of FIG. 15B, a first hinge deposition layer 1512 is represented over the spacer layer 1510 and in the via gaps 1511. In the cross-sectional view 1500C of FIG. 15C, a second hinge deposition layer 1514 is represented over the first hinge deposition layer 1512. In the cross-sectional view 1500D, a third hinge deposition layer 1516 is represented over the second hinge deposition layer 1514. In some examples, the first hinge deposition layer 1512 includes TiAl3, the second hinge deposition layer 1514 includes TiN, and the third hinge deposition layer 1516 includes AITiSi.

The cross-sectional view 1500E of FIG. 5E shows results of hinge oxide deposition (e.g., block 1436 in the fabrication method 1430 in FIG. 14C). In the cross-sectional view 1500E of FIG. 15E, a hinge oxide layer 1518 is represented over the third hinge deposition layer 1516. The cross-sectional view 1500F of FIG. 5F shows results of hinge oxide BARC coating (e.g., block 1438 in the fabrication method 1430 in FIG. 14C). In the cross-sectional view 1500F of FIG. 15F, a hinge oxide BARC coat 1520 is represented over the hinge oxide layer 1518. The cross-sectional views 1500G, 1500H, 1500I, and 1500J of FIG. 15G to FIG. 15J show the results of hinge oxide/BARC etching (e.g., block 1440 in the fabrication method 1430 in FIG. 14C). In the cross-sectional view 1500G of FIG. 15G, the hinge oxide BARC coat 1520 has been etched with some remaining in the via gaps 1511. In the cross-sectional view 1500H of FIG. 15H, the hinge oxide layer 1518 has been etched with some remaining in the via sidewalls. In the cross-sectional view 1500I of FIG. 15I, the second hinge deposition layer 1514 has been etched with some remaining in the via gaps 1511. In the cross-sectional view 1500J of FIG. 15J, the third hinge deposition layer 1516 has been etched (e.g., wet-etching aluminum of the third hinge deposition layer 1516) with some remaining in the via gaps 1511.

The cross-sectional view 1500K of FIG. 15K shows the results of TiN pattern (e.g., block 1444 in the fabrication method 1430 in FIG. 14C). In the cross-sectional view 1500K of FIG. 15K, a photoresist layer 1522 is added over the second hinge deposition layer (also known as TiN) 1514. The cross-sectional view 1500L of FIG. 15L shows the result of TiN etch (e.g., block 1446 in the fabrication method 1430 in FIG. 14C). In the cross-sectional view 1500L of FIG. 15L, the second hinge deposition layer 1514 is etched except under the photoresist layer 1522, which remains over some of the second hinge deposition layer 1514. The cross-sectional view 1500M of FIG. 15M shows the results of TiN pattern and etch (e.g., blocks 1444 and 1446 in the fabrication method 1430 in FIG. 14C). In the cross-sectional view 1500M of FIG. 15M, the photoresist layer 1522 is removed and a patterned second hinge deposition layer 1514 remains. The cross-sectional view 1500N of FIG. 15N shows the results of another pattern corresponding to a hinge pattern (e.g., block 1448 in the fabrication method 1430 in FIG. 14C). In the cross-sectional view 1500N of FIG. 15N, a photoresist layer 1524 is added over the remaining second hinge deposition layer 1514 and most of the first hinge deposition layer 1512 (covering the via gaps 1511), where the photoresist layer 1524 is exposed to form a target hinge pattern. The cross-sectional view 1500O of FIG. 15O shows the results of hinge etch (e.g., block 1450 in the fabrication method 1430 in FIG. 14C). In the cross-sectional view 1500O of FIG. 15O, areas of the first hinge deposition layer 1512 that are not covered by the photoresist layer 1524 are etched.

The cross-sectional view 1500P of FIG. 15P shows the results of spacer 2 steps (e.g., block 1454 in FIG. 14C). In the cross-sectional view 1500P of FIG. 15P, a spacer (sacrificial) layer 1526 is added over the spacer layer 1510 and the hinge layers (e.g., the remaining first hinge deposition layer 1512 and the remaining second hinge deposition layer 1514). The cross-sectional view 1500Q of FIG. 15Q shows the results of mirror via fabrication (e.g., block 1422 in FIG. 14B). In the cross-sectional view 1500Q of FIG. 15Q, a mirror via void 1527 has been formed in a via gap in the spacer layer 1526 using one or more iterations of the fabrication method 1400 of FIG. 14A. The cross-sectional view 1500R of FIG. 15R shows the results of mirror fabrication (e.g., block 1422 in FIG. 14B). In the cross-sectional view 1500R of FIG. 15R, mirror via 1528 has been formed in the mirror via void 1527 and a mirror 1530 has been formed over the spacer layer 1526 and the mirror via 1528 using one or more iterations of the fabrication method 1400 in FIG. 14A. The cross-sectional view 1500S of FIG. 15S shows a completed non-contact MEMS device with spacer layers 1510 and 1526 removed. The cross-sectional view 1500S is similar to the cross-sectional view in FIG. 4C of the MEMS device 400 with some layer details visible in FIG. 15S.

The cross-sectional view 1500T of FIG. 15T shows a cross-sectional view through electrodes of a non-contact MEMS device and related to the fabrication methods 1400, 1412, and 1430 in FIGS. 14A to 14C. The cross-sectional view 1500T is similar to the cross-sectional view in FIG. 4B of the MEMS device 400 with some layer details visible in FIG. 15T. In the example of FIG. 15T, the non-contact MEMS device 400 is represented and includes the substrate 403, the electrode layer 401, the mechanical layer 402, and the mirror 422. In the cross-sectional view 1500T, the metal layers 1502, 1504, 1506, and the ARC layer 1508 are represented as example components of the substrate 403. The electrodes 408A, 408B, 410B are example components of the electrode layer 401 and have been formed using the fabrication methods 1400 and 1412 in FIGS. 14A and 14B. The extensions 418C and 418D are example components of the mechanical layer 402 and have been formed using the fabrication methods 1400, 1412, and 1430 in FIGS. 14A to 14C. The mirror 422 in FIG. 15T has been formed using the fabrication methods 1400 and 1412 in FIGS. 14A and 14B.

In some examples, a MEMS device includes: a substrate; a first electrode on the substrate; a second electrode on the substrate, a first gap between the first electrode and the second electrode; a third electrode on the substrate; and a fourth electrode on the substrate, a second gap between the third electrode and the fourth electrode. The MEMS device also includes: a first electrode pad on the substrate; a second electrode pad on the substrate; and a hinge extending between the first electrode pad and the second electrode pad. The hinge has a first extension and a second extension, the first extension over the first gap and the second extension over the second gap. In such examples, the hinge is configured to: rotate to a first position in which the first extension is within the first gap and the second extension is spaced away from the second gap; and rotate to a second position in which the first extension is spaced away from the first gap and the second extension is within the second gap. In some examples, the first position is at a first angle relative to a rest position, the second position is at a second angle relative to the rest position, and the hinge is configured to: rotate to a third position in which the first extension is within the first gap and the second extension is spaced away from the second gap, the third position at a third angle relative to the rest position; and rotate to a fourth position in which the first extension is spaced away from the first gap and the second extension is within the second gap, the fourth position at a fourth angle relative to the rest position.

In some examples, the hinge includes a first portion and a second portion. The first portion of the hinge is coupled to and extends between the first and second electrode pads. The second portion of the hinge includes the first extension and the second extension. The second portion of the hinge is thicker than the first portion of the hinge.

In some examples, the MEMS device includes: a fifth electrode on the substrate, a third gap between the fifth electrode and the second electrode; and a sixth electrode on the substrate, a fourth gap between the sixth electrode and the fourth electrode. In some examples, the second portion of the hinge includes a third extension over the third gap and a fourth extension over the fourth gap, where the second portion of the hinge includes the third extension and a fourth extension.

In some examples, the MEMS device includes a controller coupled to the first electrode, the second electrode, the third electrode, the fourth electrode, the fifth electrode, and the sixth electrode. The controller is configured to rotate the hinge to a first position by: providing a first voltage to the first and fifth electrodes; and providing a second voltage to the third and sixth electrodes. The controller configured to rotate the hinge to a second position by: providing the second voltage to the first and fifth electrodes; and providing the first voltage to the third and sixth electrodes. In some examples, the controller is configured to rotate the hinge to a third position by: providing the first voltage to the first and fifth electrodes; providing the second voltage to the third and sixth electrodes; and providing a third voltage to the second and fourth electrodes. In some examples, the controller configured to rotate the hinge to a fourth position by: providing the second voltage to the first and fifth electrodes; providing the first voltage to the third and sixth electrodes; and providing the third voltage to the second and fourth electrodes. In some examples, the MEMS device includes: a mirror; and a mirror via coupled between the mechanical layer and the mirror.

In some examples, a MEMS device includes: a substrate; a first electrode on the substrate; a second electrode on the substrate, a first gap between the first electrode and the second electrode; a third electrode on the substrate, a fourth electrode on the substrate, a second gap between the third electrode and the fourth electrode; a first electrode pad on the substrate; a second electrode pad on the substrate. The MEMS device also includes a hinge extending between the first electrode pad and the second electrode pad. The hinge has a first extension and a second extension. The first extension is over the first gap and the second extension is over the second gap. The MEMS device is configured to: rotate the hinge to a first position in which the first extension is within the first gap and the second extension is spaced away from the second gap; and rotate the hinge to a second position in which the first extension is spaced away from the first gap and the second extension is within the second gap.

In some examples, the first position is at a first angle relative to a rest position, the second position is at a second angle relative to the rest position. In such examples, the MEMS device is configured to: rotate the hinge to a third position in which the first extension is within the first gap and the second extension is spaced away from the second gap, third position at a third angle relative to the rest position; and rotate the hinge to a fourth position in which the first extension is spaced away from the first gap and the second extension is within the second gap, the fourth position at a fourth angle relative to the rest position.

In some examples, the MEMS device includes: a fifth electrode on the substrate, a third gap between the fifth electrode and the second electrode; and a sixth electrode on the substrate, a fourth gap between the sixth electrode and the fourth electrode, where the hinge includes a third extension over the third gap and a fourth extension over the fourth gap. In such examples, the hinge includes a first portion and a second portion. The first portion of the hinge is coupled to and extends between the first and second electrode pads. The second portion of the hinge includes the first extension, the second extension, the third extension, and the fourth extension. The second portion of the hinge is thicker than the first portion of the hinge.

In some examples, the MEMS device is configured to: rotate the hinge to a first position by providing a first voltage to the first and fifth electrodes and providing a second voltage to the third and sixth electrodes. In some examples, the MEMS device is configured to rotate the hinge to a second position by providing the second voltage to the first and fifth electrodes and providing the first voltage to the third and sixth electrodes. In some examples, the MEMS device is configured to rotate the hinge to a third position by providing the first voltage to the first and fifth electrodes, providing the second voltage to the third and sixth electrodes, and providing a third voltage to the second and fourth electrodes. In some examples, the MEMS device is configured to rotate the hinge to a fourth position by providing the second voltage to the first and fifth electrodes, providing the first voltage to the third and sixth electrodes, and providing the third voltage to the second and fourth electrodes.

In some examples, a MEMS device includes: a substrate; a first electrode on the substrate; a second electrode on the substrate, a first gap between the first electrode and the second electrode; a third electrode on the substrate; a fourth electrode on the substrate, a second gap between the third electrode and the fourth electrode; a first electrode pad on the substrate; a second electrode pad on the substrate; a hinge extending between the first electrode pad and the second electrode pad, the hinge having a first extension and a second extension, the first extension over the first gap and the second extension over the second gap; a mirror; and a mirror via coupled between the hinge and the mirror.

In some examples, examples, the hinge is configured to: rotate to a first position in which the first extension is within the first gap, and the second extension is spaced away from the second gap; and rotate to a second position in which the first extension is spaced away from the first gap, and the second extension is within the second gap. In some examples, the first position is at a first angle relative to a rest position, the second position is at a second angle relative to the rest position. In such examples, the hinge is configured to: rotate to a third position in which the first extension is within the first gap and the second extension is spaced away from the second gap, the third position at a third angle relative to the rest position; and rotate to a fourth position in which the first extension is spaced away from the first gap and the second extension is within the second gap, the fourth position at a fourth angle relative to the rest position.

In some examples, the MEMS device includes: a fifth electrode on the substrate, a third gap between the fifth electrode and the second electrode; and a sixth electrode on the substrate, a fourth gap between the sixth electrode and the fourth electrode. In such examples, the hinge includes a first portion and a second portion. The first portion of the hinge is coupled to and extends between the first and second electrode pads. The hinge includes a third extension over the third gap and a fourth extension over the fourth gap. The second portion of the hinge includes the first extension, the second extension, the third extension, and the fourth extension. The second portion of the hinge is thicker than the first portion of the hinge.

In some examples, the MEMS device includes a controller coupled to the first electrode, the second electrode, the third electrode, the fourth electrode, the fifth electrode, and the sixth electrode. In such examples, the controller is configured to rotate the mirror to a first position by: providing a first voltage to the first and fifth electrodes; and providing a second voltage to the third and sixth electrodes. The controller configured to rotate the mirror to a second position by: providing the second voltage to the first and fifth electrodes; and providing the first voltage to the third and sixth electrodes. In some examples, the controller is configured to rotate the mirror to a third position by: providing the first voltage to the first and fifth electrodes; providing the second voltage to the third and sixth electrodes; and providing a third voltage to the second and fourth electrodes. The controller configured to rotate the mirror to a fourth position by: providing the second voltage to the first and fifth electrodes; providing the first voltage to the third and sixth electrodes; and providing the third voltage to the second and fourth electrodes.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. A microelectromechanical system (MEMS) device comprising:
a substrate;
a first electrode on the substrate;
a second electrode on the substrate, a first gap between the first electrode and the second electrode;
a third electrode on the substrate;
a fourth electrode on the substrate, a second gap between the third electrode and the fourth electrode;
a first electrode pad on the substrate;
a second electrode pad on the substrate; and
a hinge extending between the first electrode pad and the second electrode pad, the hinge having a first extension and a second extension, the first extension over the first gap and the second extension over the second gap.

2. The MEMS device of claim 1, wherein the hinge is configured to:
rotate to a first position in which the first extension is within the first gap and the second extension is spaced away from the second gap; and
rotate to a second position in which the first extension is spaced away from the first gap and the second extension is within the second gap.

3. The MEMS device of claim 2, wherein the first position is at a first angle relative to a rest position, the second position is at a second angle relative to the rest position, and the hinge is configured to:
rotate to a third position in which the first extension is within the first gap and the second extension is spaced away from the second gap, the third position at a third angle relative to the rest position; and
rotate to a fourth position in which the first extension is spaced away from the first gap and the second extension is within the second gap, the fourth position at a fourth angle relative to the rest position.

4. The MEMS device of claim 1, wherein the hinge includes a first portion and a second portion, the first portion of the hinge coupled to and extending between the first and second electrode pads, the second portion of the hinge including the first extension and the second extension, and the second portion of the hinge thicker than the first portion of the hinge.

5. The MEMS device of claim 4, further comprising:
a fifth electrode on the substrate, a third gap between the fifth electrode and the second electrode; and
a sixth electrode on the substrate, a fourth gap between the sixth electrode and the fourth electrode, wherein the second portion of the hinge includes a third extension over the third gap and a fourth extension over the fourth gap, wherein the second portion of the hinge includes the third extension and the fourth extension.

6. The MEMS device of claim 5, further comprising a controller coupled to the first electrode, the second electrode, the third electrode, the fourth electrode, the fifth electrode, and the sixth electrode,
the controller configured to rotate the hinge to a first position by:
providing a first voltage to the first and fifth electrodes; and
providing a second voltage to the third and sixth electrodes, and
the controller configured to rotate the hinge to a second position by:
providing the second voltage to the first and fifth electrodes; and
providing the first voltage to the third and sixth electrodes.

7. The MEMS device of claim 6,
wherein the controller is configured to rotate the hinge to a third position by:
providing the first voltage to the first and fifth electrodes;
providing the second voltage to the third and sixth electrodes; and
providing a third voltage to the second and fourth electrodes, and
the controller configured to rotate the hinge to a fourth position by:
providing the second voltage to the first and fifth electrodes;
providing the first voltage to the third and sixth electrodes; and
providing the third voltage to the second and fourth electrodes.

8. The MEMS device of claim 2, further comprising:
a mirror; and
a mirror via coupled between the hinge and the mirror.

9. A microelectromechanical system (MEMS) device, comprising:
a first electrode;
a second electrode, a first gap between the first electrode and the second electrode;
a third electrode,
a fourth electrode, a second gap between the third electrode and the fourth electrode;
a hinge between the first and the second electrodes and the second and third electrodes, the hinge having a first extension and a second extension, and the first extension over the first gap and the second extension over the second gap, wherein the MEMS device is configured to:
rotate the hinge to a first position in which the first extension is within the first gap and the second extension is spaced away from the second gap; and
rotate the hinge to a second position in which the first extension is spaced away from the first gap and the second extension is within the second gap.

10. The MEMS device of claim 9, wherein the first position is at a first angle relative to a rest position, the second position is at a second angle relative to the rest position, and the MEMS device is configured to:
rotate the hinge to a third position in which the first extension is within the first gap and the second extension is spaced away from the second gap, the third position at a third angle relative to the rest position; and
rotate the hinge to a fourth position in which the first extension is spaced away from the first gap and the second extension is within the second gap, the fourth position at a fourth angle relative to the rest position.

11. The MEMS device of claim 9, further comprising:
a fifth electrode, a third gap between the fifth electrode and the second electrode; and
a sixth electrode, a fourth gap between the sixth electrode and the fourth electrode, wherein the hinge includes a third extension over the third gap and a fourth extension over the fourth gap.

12. The MEMS device of claim 11, further comprising:
a first electrode pad; and
a second electrode pad, wherein the hinge includes a first portion and a second portion, the first portion of the hinge coupled to and extending between the first and second electrode pads, the second portion of the hinge including the first extension, the second extension, the third extension, and the fourth extension, and the second portion of the hinge thicker than the first portion of the hinge.

13. The MEMS device of claim 11, wherein the MEMS device is configured to:
rotate the hinge to a first position by providing a first voltage to the first and fifth electrodes and providing a second voltage to the third and sixth electrodes, and
rotate the hinge to a second position by providing the second voltage to the first and fifth electrodes and providing the first voltage to the third and sixth electrodes.

14. The MEMS device of claim 13, wherein the MEMS device is configured to:
rotate the hinge to a third position by providing the first voltage to the first and fifth electrodes, providing the second voltage to the third and sixth electrodes, and providing a third voltage to the second and fourth electrodes; and
rotate the hinge to a fourth position by providing the second voltage to the first and fifth electrodes, providing the first voltage to the third and sixth electrodes, and providing the third voltage to the second and fourth electrodes.

15. A microelectromechanical system (MEMS) device comprising:
a substrate;
a first electrode on the substrate;
a second electrode on the substrate, a first gap between the first electrode and the second electrode;
a third electrode on the substrate;
a fourth electrode on the substrate, a second gap between the third electrode and the fourth electrode;
a first electrode pad on the substrate;
a second electrode pad on the substrate;
a hinge extending between the first electrode pad and the second electrode pad, the hinge having a first extension and a second extension, the first extension over the first gap and the second extension over the second gap;
a mirror; and
a mirror via between the hinge and the mirror.

16. The MEMS device of claim 15, wherein the hinge is configured to:
rotate to a first position in which the first extension is within the first gap, and the second extension is spaced away from the second gap; and
rotate to a second position in which the first extension is spaced away from the first gap, and the second extension is within the second gap.

17. The MEMS device of claim 16, wherein the first position is at a first angle relative to a rest position, the second position is at a second angle relative to the rest position, and the hinge is configured to:
rotate to a third position in which the first extension is within the first gap and the second extension is spaced away from the second gap, the third position at a third angle relative to the rest position; and
rotate to a fourth position in which the first extension is spaced away from the first gap and the second extension is within the second gap, the fourth position at a fourth angle relative to the rest position.

18. The MEMS device of claim 15, further comprising:
a fifth electrode on the substrate, a third gap between the fifth electrode and the second electrode; and
a sixth electrode on the substrate, a fourth gap between the sixth electrode and the fourth electrode, wherein the hinge includes a first portion and a second portion, the first portion of the hinge coupled to and extending between the first and second electrode pads, the hinge including a third extension over the third gap and a fourth extension over the fourth gap, the second portion of the hinge including the first extension, the second extension, the third extension, and the fourth extension, and the second portion of the hinge thicker than the first portion of the hinge.

19. The MEMS device of claim 18, further comprising a controller coupled to the first electrode, the second electrode, the third electrode, the fourth electrode, the fifth electrode, and the sixth electrode,
the controller configured to rotate the mirror to a first position by:
providing a first voltage to the first and fifth electrodes; and
providing a second voltage to the third and sixth electrodes, and
the controller configured to rotate the mirror to a second position by:
providing the second voltage to the first and fifth electrodes; and
providing the first voltage to the third and sixth electrodes.

20. The MEMS device of claim 19,
wherein the controller is configured to rotate the mirror to a third position by:
providing the first voltage to the first and fifth electrodes;
providing the second voltage to the third and sixth electrodes; and
providing a third voltage to the second and fourth electrodes, and
the controller configured to rotate the mirror to a fourth position by:
providing the second voltage to the first and fifth electrodes;
providing the first voltage to the third and sixth electrodes; and
providing the third voltage to the second and fourth electrodes.
